(19) United States
(12) Patent Application Publication
(10) Pub. No.: US 2023/0014898 A1
(43) Pub. Date: Jan. 19, 2023

(54) METHODS AND APPARATUS TO IMPROVE PIN CONTACT OF A COMPONENT STACK

(71) Applicant: Intel Corporation, Santa Clara, CA (US)

(72) Inventors: Phil Geng, Washougal, WA (US); Jordan Johnson, North Plains, OR (US); Mengqi Liu, Hillsboro, OR (US); Ralph Miele, Hillsboro, OR (US); Min Pei, Camas, WA (US)

(21) Appl. No.: 17/955,210

(22) Filed: Sep. 28, 2022

(51) Int. Cl. H01R 12/70; H01R 12/82; H01R 43/26; H05K 7/14

(52) U.S. Cl. CPC H01R 12/7076; H01R 12/82; H01R 43/26; H05K 7/1405

(57) ABSTRACT

Methods, apparatus, systems, and articles of manufacture to improve pin contact are disclosed. An apparatus disclosed herein includes a back plate, a circuit board disposed between the back plate and a socket, and a spring sheet disposed between the back plate and the circuit board.

### FIELD OF THE DISCLOSURE

This disclosure relates generally to compute unit retention systems and, more particularly, to method and apparatus to improve pin contact.

### BACKGROUND

The demand for greater computing power and faster computing times continues to grow. This has led to higher-density connectors on computer hardware components to transfer signals more quickly. Some compute units are communicatively coupled to printed circuit boards via sockets such as land grid array (LGA) sockets.

### BRIEF DESCRIPTION OF THE DRAWINGS

FIG. 1 illustrates one or more example environments in which teachings of this disclosure may be implemented.

FIG. 2 illustrates at least one example of a data center for executing workloads with disaggregated resources.

FIG. 3 illustrates at least one example of a pod that may be included in the data center of FIG. 2.

FIG. 4 is a perspective view of at least one example of a rack that may be included in the pod of FIG. 3.

FIG. 5 is a side elevation view of the rack of FIG. 4.

FIG. 6 is a perspective view of the rack of FIG. 4 having a sled mounted therein.

FIG. 7 is a is a block diagram of at least one example of a top side of the sled of FIG. 6.

FIG. 8 is a block diagram of at least one example of a bottom side of the sled of FIG. 7.

FIG. 9 is a block diagram of at least one example of a compute sled usable in the data center of FIG. 2.

FIG. 10 is a top perspective view of at least one example of the compute sled of FIG. 9.

FIG. 11 is a block diagram of at least one example of an accelerator sled usable in the data center of FIG. 2.

FIG. 12 is a top perspective view of at least one example of the accelerator sled of FIG. 10.

FIG. 13 is a block diagram of at least one example of a storage sled usable in the data center of FIG. 2.

FIG. 14 is a top perspective view of at least one example of the storage sled of FIG. 13.

FIG. 15 is a block diagram of at least one example of a memory sled usable in the data center of FIG. 2.

FIG. 16 is a block diagram of a system that may be established within the data center of FIG. 2 to execute workloads with managed nodes composed of disaggregated resources.

FIG. 17 is an exploded view of a prior component stack including an integrated circuit, a prior socket, and a prior back plate assembly.

FIG. 18 is a diagram of a side view of the prior component stack of FIG. 18.

FIG. 19A is a diagram of a side view of a prior back plate and shim.

FIG. 19B is a top view of the prior back plate and shim of FIG. 19A.

FIGS. 20-22 are diagrams of side views of an example back plate including a spring sheet implemented in accordance with teachings of this disclosure.

FIG. 23 is a diagram of a side view of another example back plate including a spring sheet implemented in accordance with teachings of this disclosure.

FIG. 24 is a diagram of a side view of another example back plate including a spring sheet implemented in accordance with teachings of this disclosure.

FIG. 25 is a perspective view of another example back plate including a spring sheet implemented in accordance with teachings of this disclosure.

FIGS. 26-29 are diagrams of side views of a pre-shaped back plate implemented in accordance with teachings of this disclosure.

FIGS. 30-32 are diagrams of side views of an example back plate including a spacer implemented in accordance with teachings of this disclosure.

FIG. 33 is an illustration of the prior component stack of FIGS. 17 and 18 illustrating the load distribution thereon.

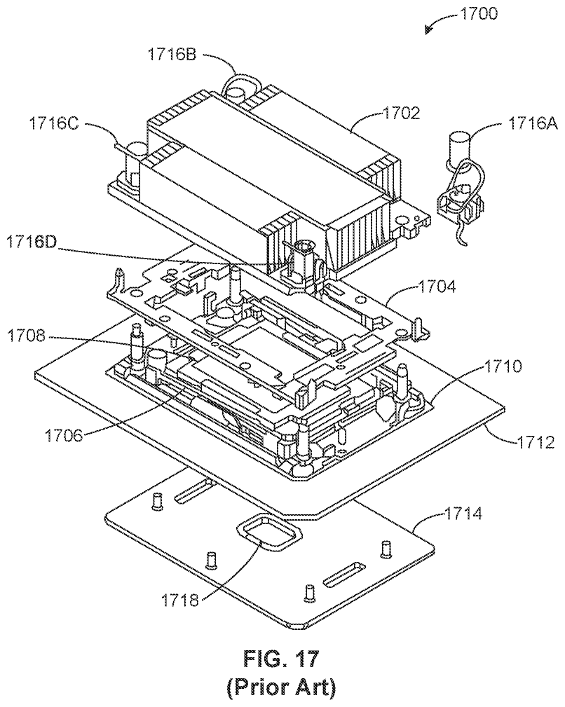

FIG. 31 is an illustration of the expected bending of the back plate of FIG. 17 caused by socket loading.

FIG. 35 is an illustration of the expected bending of the PCB of FIG. 17 caused by socket loading.

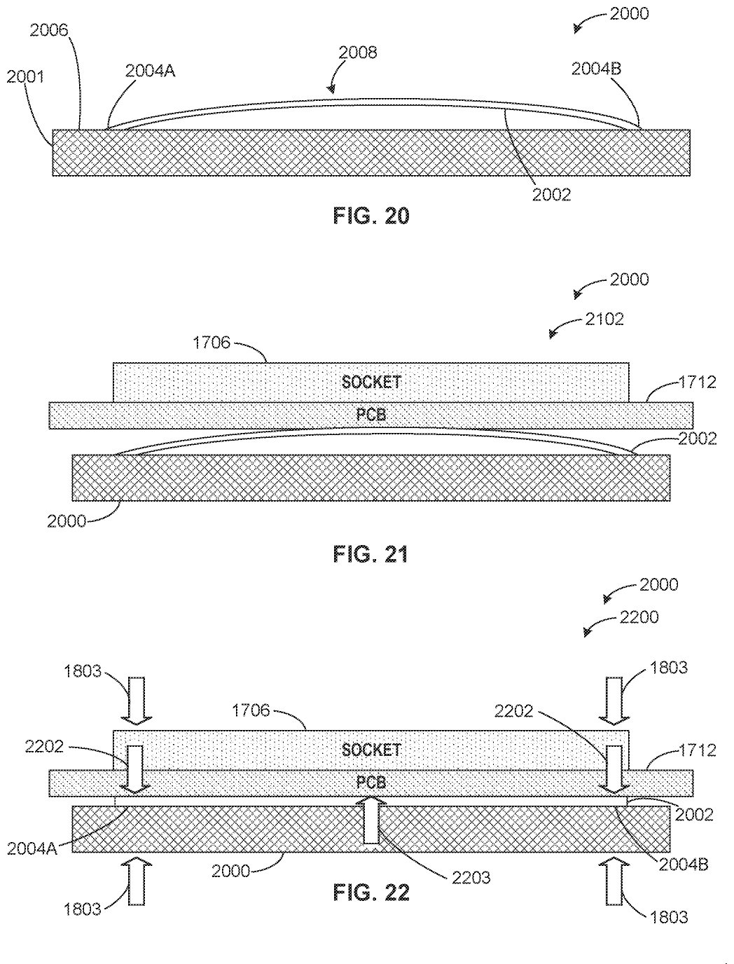

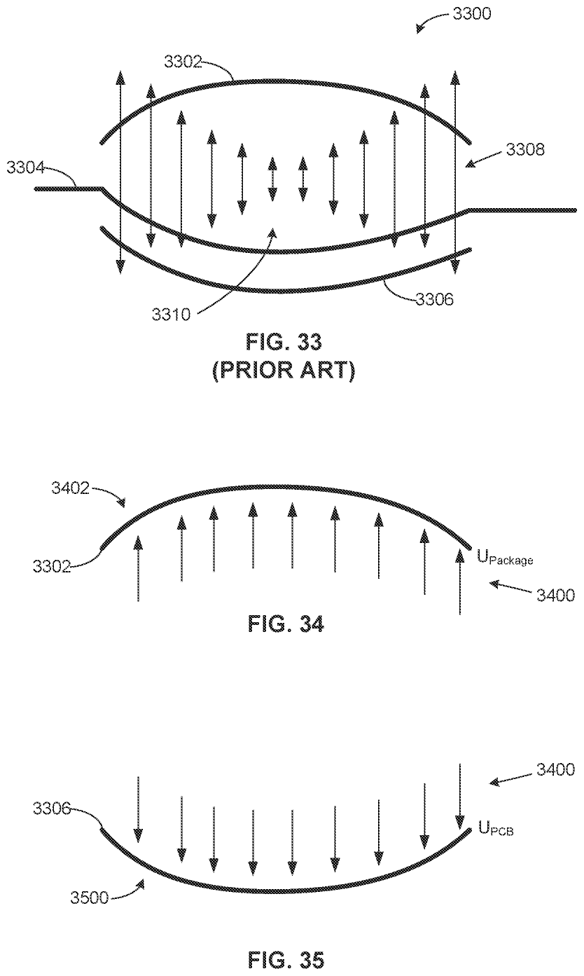

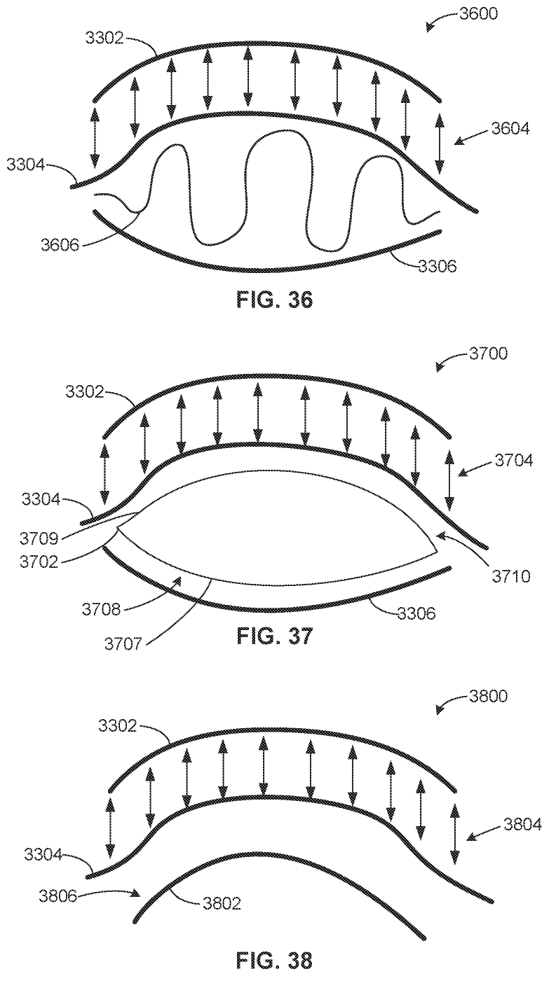

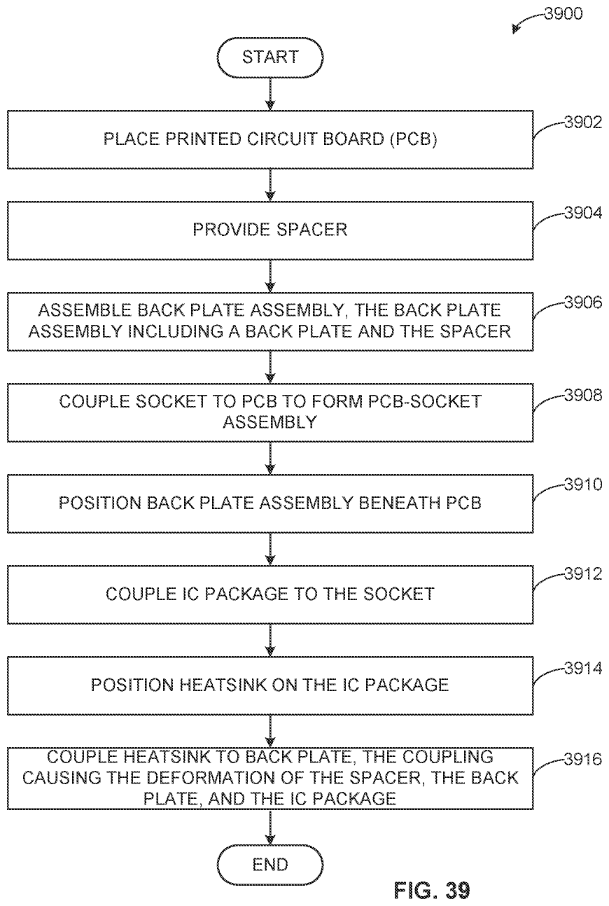

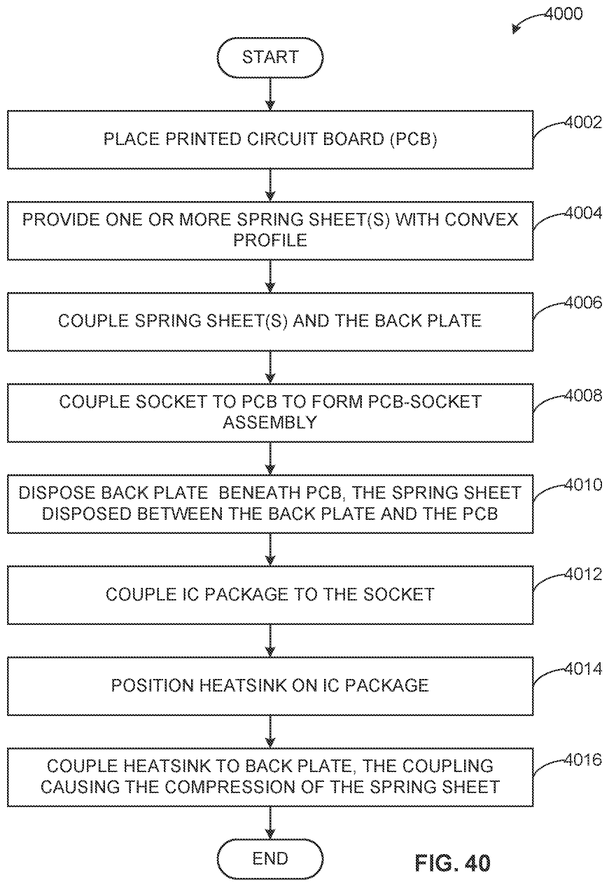

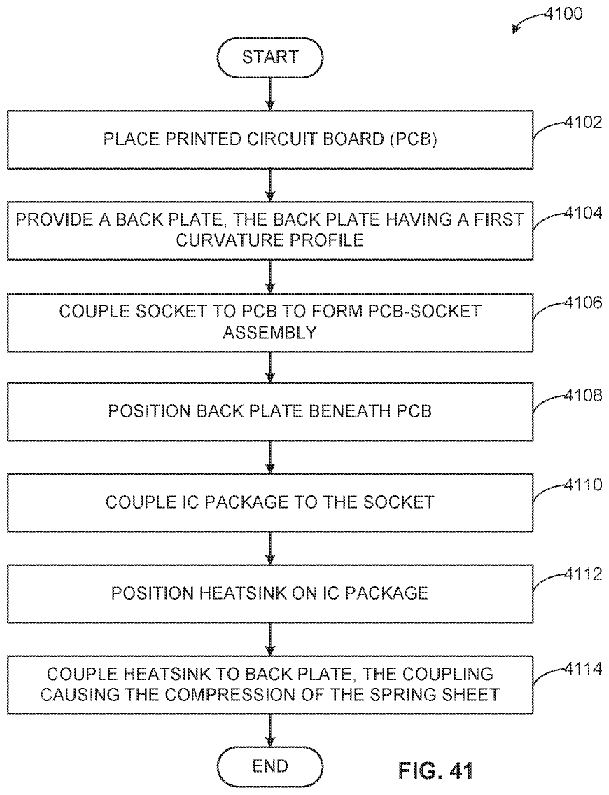

FIG. 33 is an illustration of the back plates and the spring sheets of FIGS. 20-25.

FIG. 37 is an illustration of the back plate and spacer implemented in accordance with teachings of this disclosure.

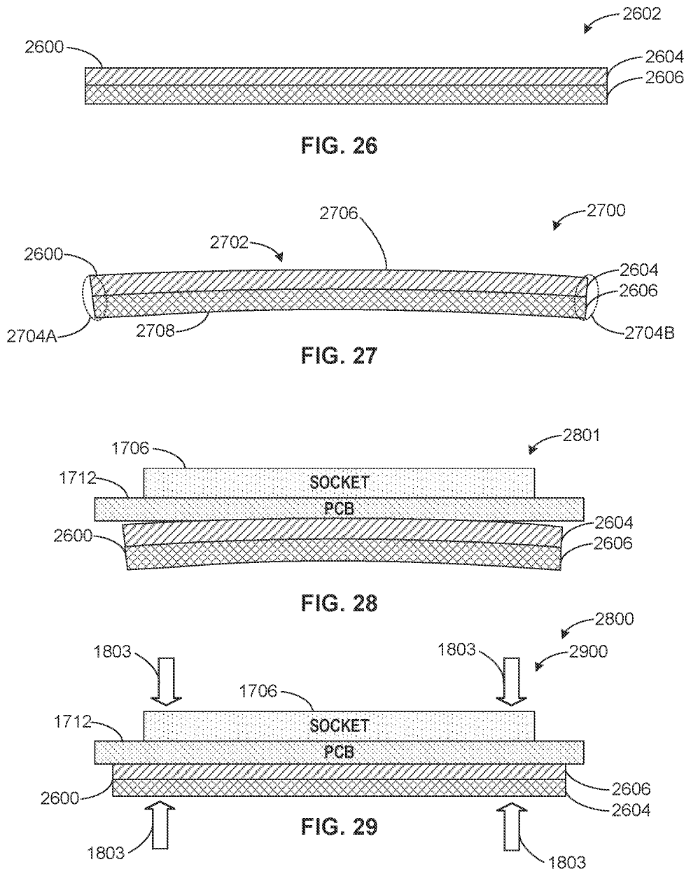

FIG. 38 is an illustration of the pre-shaped back plates of FIGS. 26-29.

FIG. 39 is a flow diagram of example operations that can be used to assemble the back plate and spacer of FIG. 37.

FIG. 40 is a flow diagram of example operations that can be used to assemble the back plate spring sheet assemblies of FIG. 20-25.

FIG. 41 is a flow diagram of example operations that can be used to assemble the back plate spring sheet assemblies of FIG. 26-29.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

Integrated circuits, such as central processing units (CPUs) are often coupled to printed circuit boards (PCBs) via sockets. Many sockets, including land grid array (LGA) sockets, include a plurality of pins that receive and electrically couple to corresponding features (e.g., contacts or lands) of the integrated circuit. To ensure that the integrated circuit is able to communicate with the circuit board, the pins of the socket must remain in contact with the integrated circuit. In many examples, the contact force between the pins of the socket and the integrated circuit is provided by one or more fasteners coupled between a heatsink, disposed above the integrated circuit (e.g., opposite the socket), and a back plate disposed below the printed circuit board (e.g., on an opposite side to the socket and integrated circuit). However, such fasteners can cause warpage of the back plate and printed circuit board, which can reduce the contact force in particular areas of the socket. In recent years, the pin density of sockets and associated required contact force have increased to compensate for the greater processing power of integrated circuits. Accordingly, the back plate warpage can reduce the performance of the integrated circuit due to the reduced contact between the integrated circuit and the socket on the printed circuit board.

Examples disclosed herein improve pin contact between the sockets of printed circuit boards and the associated integrated circuits by compensating for back plate warpage. Some examples disclosed herein include a pre-shaped back plate coupled beneath the printed circuit board. In some such examples disclosed herein, the curvature of the pre-shaped back plate causes the back plate to flatten when subj ected to socket loading, thereby ensuring uniform socket pin contact force over all areas of the socket. Some examples disclosed herein include spring sheets disposed between the printed circuit board and the back plate. In some such examples disclosed herein, the spring sheets increase the compressive load in areas of the socket with comparatively low contact force. Some examples disclosed herein include spring sheets disposed on the edges of the back plate to damp vibrations generated by the operation of the integrated circuit and/or printed circuit board. Some examples disclosed herein include a spacer disposed between the back plate and the printed circuit board to compensate for the warpage of the back plate.

As used herein, unless otherwise stated, the term “above” describes the relationship of two parts relative to Earth, when those parts are mounted vertically (e.g., the centerline axis of those parts are aligned with the gravitational vector, etc.). A first part is above a second part, if the second part has at least one part between Earth and the first part. Likewise, as used herein, a first part is “below” a second part when the first part is closer to the Earth than the second part, when those parts are mounted vertically (e.g., the centerline axis of those parts are aligned with the gravitational vector, etc.). As noted above, a first part can be above or below a second part with one or more of: other parts therebetween, without other parts therebetween, with the first and second parts touching, or without the first and second parts being in direct contact with one another.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly that might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified in the below description. As used herein “substantially equal” refers to quantities that are with 10% of one another. As used herein “substantially real time” refers to occurrence in a near instantaneous manner recognizing there may be real world delays for computing time, transmission, etc. Thus, unless otherwise specified, “substantially real time” refers to real time+/−1 second. As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “processor circuitry” is defined to include (i) one or more special purpose electrical circuits structured to perform specific operation(s) and including one or more semiconductor-based logic devices (e.g., electrical hardware implemented by one or more transistors), and/or (ii) one or more general purpose semiconductor-based electrical circuits programmable with instructions to perform specific operations and including one or more semiconductor-based logic devices (e.g., electrical hardware implemented by one or more transistors). Examples of processor circuitry include programmable microprocessors, Field Programmable Gate Arrays (FPGAs) that may instantiate instructions, Central Processor Units (CPUs), Graphics Processor Units (GPUs), Digital Signal Processors (DSPs), XPUs, or microcontrollers and integrated circuits such as Application Specific Integrated Circuits (ASICs). For example, an XPU may be implemented by a heterogeneous computing system including multiple types of processor circuitry (e.g., one or more FPGAs, one or more CPUs, one or more GPUs, one or more DSPs, etc., and/or a combination thereof) and application programming interface(s) (API(s)) that may assign computing task(s) to whichever one(s) of the multiple types of processor circuitry is/are best suited to execute the computing task(s).

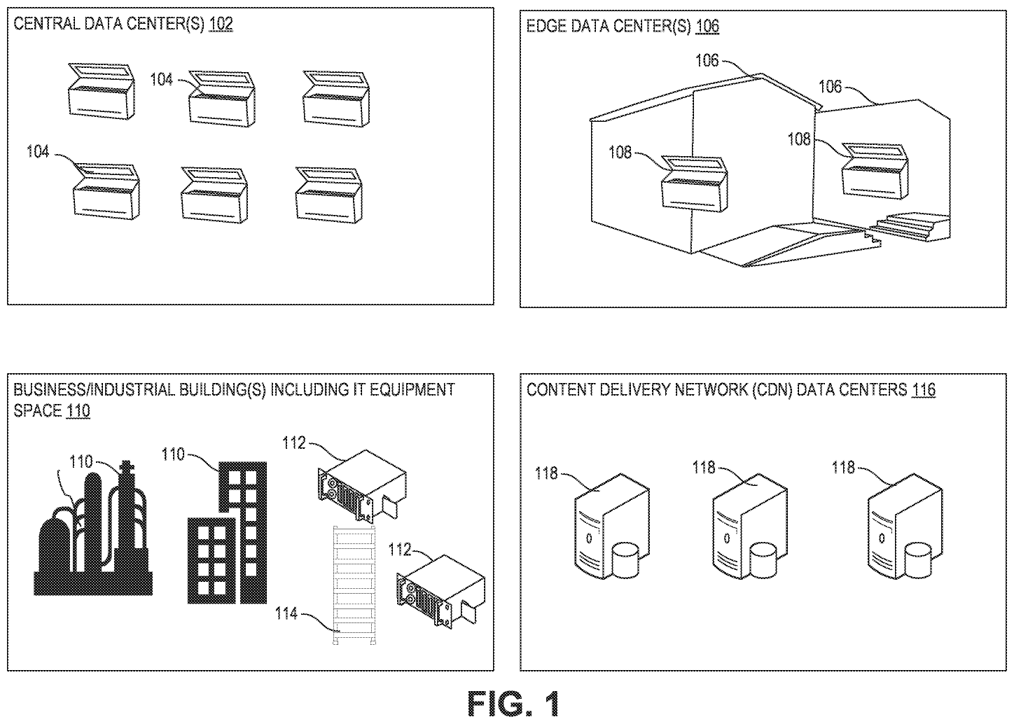

FIG. 1 illustrates one or more example environments in which teachings of this disclosure may be implemented. The example environment(s) of FIG. 1 can include one or more central data centers 102. The central data center(s) 102 can store a large number of servers used by, for instance, one or more organizations for data processing, storage, etc. As illustrated in FIG. 1, the central data center(s) 102 include a plurality of immersion tank(s) 104 to facilitate cooling of the servers and/or other electronic components stored at the central data center(s) 102. The immersion tank(s) 104 can provide for single-phase immersion cooling or two-phase immersion cooling.

The example environments of FIG. 1 can be part of an edge computing system. For instance, the example environments of FIG. 1 can include edge data centers or micro-data centers 106. The edge data center(s) 106 can include, for example, data centers located at a base of a cell tower. In some examples, the edge data center(s) 106 are located at or near a top of a cell tower and/or other utility pole. The edge data center(s) 106 include respective housings that store server(s), where the server(s) can be in communication with, for instance, the server(s) stored at the central data center(s) 102, client devices, and/or other computing devices in the edge network. Example housings of the edge data center(s) 106 may include materials that form one or more exterior surfaces that partially or fully protect contents therein, in which protection may include weather protection, hazardous environment protection (e.g., EMI, vibration, extreme temperatures), and/or enable submergibility. Example housings may include power circuitry to provide power for stationary and/or portable implementations, such as AC power inputs, DC power inputs, AC/DC or DC/AC converter(s), power regulators, transformers, charging circuitry, batteries, wired inputs and/or wireless power inputs. As illustrated in FIG. 1, the edge data center(s) 106 can include immersion tank(s) 108 to store server(s) and/or other electronic component(s) located at the edge data center(s) 106.

The example environment(s) of FIG. 1 can include buildings 110 for purposes of business and/or industry that store information technology (IT) equipment in, for example, one or more rooms of the building(s) 110. For example, as represented in FIG. 1, server(s) 112 can be stored with server rack(s) 114 that support the server(s) 112 (e.g., in an opening of slot of the rack 114). In some examples, the server(s) 112 located at the buildings 110 include on-premise server(s) of an edge computing network, where the on-premise server(s) are in communication with remote server(s) (e.g., the server(s) at the edge data center(s) 106) and/or other computing device(s) within an edge network.

The example environment(s) of FIG. 1 include content delivery network (CDN) data center(s) 116. The CDN data center(s) 116 of this example include server(s) 118 that cache content such as images, webpages, videos, etc. accessed via user devices. The server(s) 118 of the CDN data centers 116 can be disposed in immersion cooling tank(s) such as the immersion tanks 104, 108 shown in connection with the data centers 102, 106.

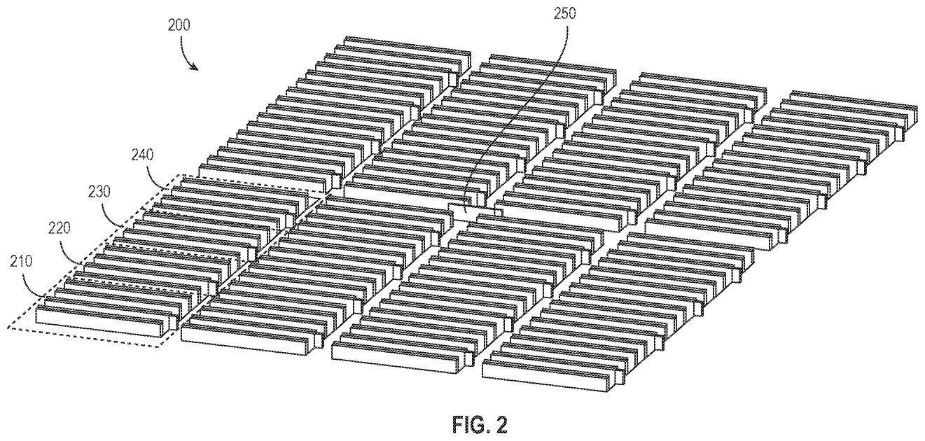

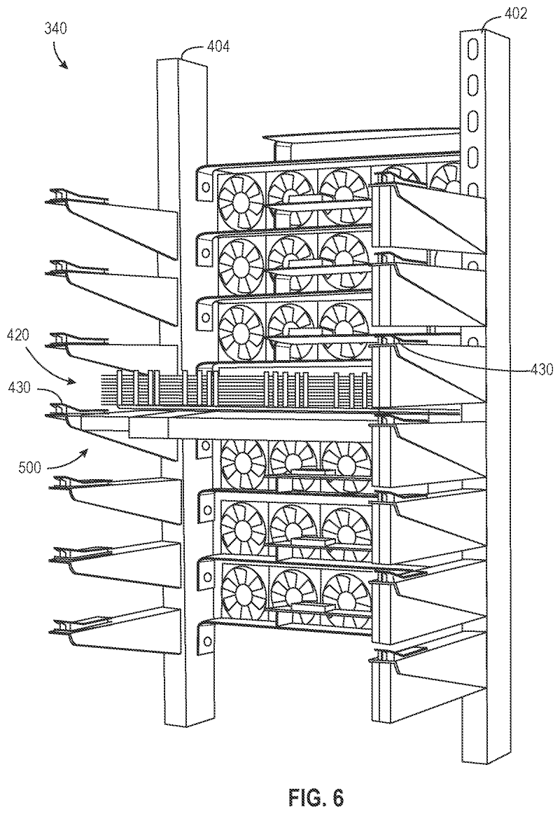

In some instances, the example data centers 102, 106, 116 and/or building(s) 110 of FIG. 1 include servers and/or other electronic components that are cooled independent of immersion tanks (e.g., the immersion tanks 104, 108) and/or an associated immersion cooling system. That is, in some examples, some or all of the servers and/or other electronic components in the data centers 102, 106, 116 and/or building(s) 110 can be cooled by air. Thus, in some examples, the immersion tanks 104, 108 of FIG. 1 may be omitted. Further, the example data centers 102, 106, 116 and/or building(s) 110 of FIG. 1 can correspond to, be implemented by, and/or be adaptations of the example data center 200 described in further detail below in connection with FIGS. 2-16.

Although a cooling tank and other components are shown in the figure, any number of such components may be present. The example cooling data centers and/or other structures or environments disclosed herein are not limited to arrangements of the size that are depicted in FIG. 1. For instance, the structures containing example cooling systems and/or components thereof disclosed herein can be of a size that includes an opening to accommodate service personnel, such as the example data center(s) 106 of FIG. 1, but can also be smaller (e.g., a “doghouse” enclosure). For instance, the structures containing example cooling systems and/or components thereof disclosed herein can be sized such that access (e.g., the only access) to an interior of the structure is a port for service personnel to reach into the structure. Also, the structures containing example cooling systems and/or components thereof disclosed herein can be sized such that only a tool can reach into the enclosure because the structure may be supported by, for a utility pole or radio tower, or a larger structure.

FIG. 2 illustrated an example data center 200 in which disaggregated resources may cooperatively execute one or more workloads (e.g., applications on behalf of customers). The illustrated data center 200 includes multiple platforms 210, 220, 230, 240 (referred to herein as pods), each of which includes one or more rows of racks. Of course, although the data center 200 is shown with multiple pods, in some examples, the data center 200 may be implemented as a single pod. As described in more detail herein, a rack may house multiple sleds. A sled may be primarily equipped with a particular type of resource (e.g., memory devices, data storage devices, accelerator devices, general purpose processors), i.e., resources that can be logically coupled to form a composed node. Some such nodes may act as, for example, a server. In the illustrative example, the sleds in the pods 210, 220, 230, 240 are connected to multiple pod switches (e.g., switches that route data communications to and from sleds within the pod). The pod switches, in turn, connect with spine switches 250 that switch communications among pods (e.g., the pods 210, 220, 230, 240) in the data center 200. In some examples, the sleds may be connected with a fabric using Intel Omni-Path™ technology. In other examples, the sleds may be connected with other fabrics, such as InfiniBand or Ethernet. As described in more detail herein, resources within the sleds in the data center 200 may be allocated to a group (referred to herein as a “managed node”) containing resources from one or more sleds to be collectively utilized in the execution of a workload. The workload can execute as if the resources belonging to the managed node were located on the same sled. The resources in a managed node may belong to sleds belonging to different racks, and even to different pods 210, 220, 230, 240. As such, some resources of a single sled may be allocated to one managed node while other resources of the same sled are allocated to a different managed node (e.g., first processor circuitry assigned to one managed node and second processor circuitry of the same sled assigned to a different managed node).

A data center including disaggregated resources, such as the data center 200, can be used in a wide variety of contexts, such as enterprise, government, cloud service provider, and communications service provider (e.g., Telco's), as well in a wide variety of sizes, from cloud service provider mega-data centers that consume over 200,000 sq. ft. to single- or multi-rack installations for use in base stations.

In some examples, the disaggregation of resources is accomplished by using individual sleds that include predominantly a single type of resource (e.g., compute sleds including primarily compute resources, memory sleds including primarily memory resources). The disaggregation of resources in this manner, and the selective allocation and deallocation of the disaggregated resources to form a managed node assigned to execute a workload, improves the operation and resource usage of the data center 200 relative to typical data centers. Such typical data centers include hyperconverged servers containing compute, memory, storage and perhaps additional resources in a single chassis. For example, because a given sled will contain mostly resources of a same particular type, resources of that type can be upgraded independently of other resources. Additionally, because different resource types (processors, storage, accelerators, etc.) typically have different refresh rates, greater resource utilization and reduced total cost of ownership may be achieved. For example, a data center operator can upgrade the processor circuitry throughout a facility by only swapping out the compute sleds. In such a case, accelerator and storage resources may not be contemporaneously upgraded and, rather, may be allowed to continue operating until those resources are scheduled for their own refresh. Resource utilization may also increase. For example, if managed nodes are composed based on requirements of the workloads that will be running on them, resources within a node are more likely to be fully utilized. Such utilization may allow for more managed nodes to run in a data center with a given set of resources, or for a data center expected to run a given set of workloads, to be built using fewer resources.

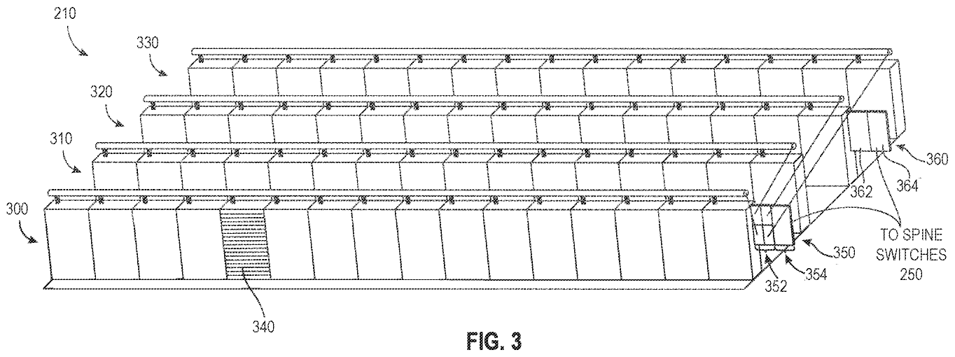

Referring now to FIG. 3, the pod 210, in the illustrative example, includes a set of rows 300, 310, 320, 330 of racks 340. Individual ones of the racks 340 may house multiple sleds (e.g., sixteen sleds) and provide power and data connections to the housed sleds, as described in more detail herein. In the illustrative example, the racks are connected to multiple pod switches 350, 360. The pod switch 350 includes a set of ports 352 to which the sleds of the racks of the pod 210 are connected and another set of ports 354 that connect the pod 210 to the spine switches 250 to provide connectivity to other pods in the data center 200. Similarly, the pod switch 360 includes a set of ports 362 to which the sleds of the racks of the pod 210 are connected and a set of ports 364 that connect the pod 210 to the spine switches 250. As such, the use of the pair of switches 350, 360 provides an amount of redundancy to the pod 210. For example, if either of the switches 350, 360 fails, the sleds in the pod 210 may still maintain data communication with the remainder of the data center 200 (e.g., sleds of other pods) through the other switch 350, 360. Furthermore, in the illustrative example, the switches 250, 350, 360 may be implemented as dual-mode optical switches, capable of routing both Ethernet protocol communications carrying Internet Protocol (IP) packets and communications according to a second, high-performance link-layer protocol (e.g., PCI Express) via optical signaling media of an optical fabric.

It should be appreciated that any one of the other pods 220, 230, 240 (as well as any additional pods of the data center 200) may be similarly structured as, and have components similar to, the pod 210 shown in and disclosed in regard to FIG. 3 (e.g., a given pod may have rows of racks housing multiple sleds as described above). Additionally, while two pod switches 350, 360 are shown, it should be understood that in other examples, a different number of pod switches may be present, providing even more failover capacity. In other examples, pods may be arranged differently than the rows-of-racks configuration shown in FIGS. 2 and 3. For example, a pod may include multiple sets of racks arranged radially, i.e., the racks are equidistant from a center switch.

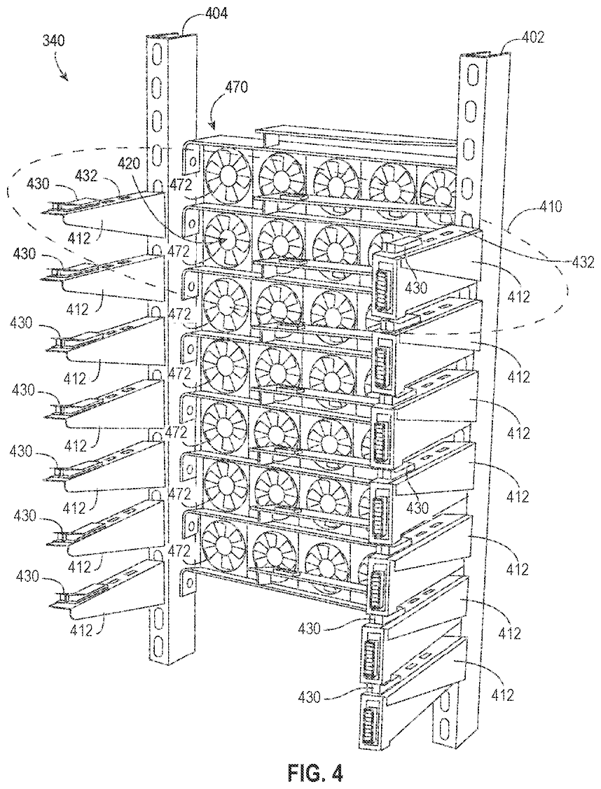

FIGS. 4-6 illustrate an example rack 340 of the data center 200. As shown in the illustrated example, the rack 340 includes two elongated support posts 402, 404, which are arranged vertically. For example, the elongated support posts 402, 404 may extend upwardly from a floor of the data center 200 when deployed. The rack 340 also includes one or more horizontal pairs 410 of elongated support arms 412 (identified in FIG. 4 via a dashed ellipse) configured to support a sled of the data center 200 as discussed below. One elongated support arm 412 of the pair of elongated support arms 412 extends outwardly from the elongated support post 402 and the other elongated support arm 412 extends outwardly from the elongated support post 404.

In the illustrative examples, at least some of the sleds of the data center 200 are chassis-less sleds. That is, such sleds have a chassis-less circuit board substrate on which physical resources (e.g., processors, memory, accelerators, storage, etc.) are mounted as discussed in more detail below. As such, the rack 340 is configured to receive the chassis-less sleds. For example, a given pair 410 of the elongated support arms 412 defines a sled slot 420 of the rack 340, which is configured to receive a corresponding chassis-less sled. To do so, the elongated support arms 412 include corresponding circuit board guides 430 configured to receive the chassis-less circuit board substrate of the sled. The circuit board guides 430 are secured to, or otherwise mounted to, a top side 432 of the corresponding elongated support arms 412. For example, in the illustrative example, the circuit board guides 430 are mounted at a distal end of the corresponding elongated support arm 412 relative to the corresponding elongated support post 402, 404. For clarity of FIGS. 4-6, not every circuit board guide 430 may be referenced in each figure. In some examples, at least some of the sleds include a chassis and the racks 340 are suitably adapted to receive the chassis.

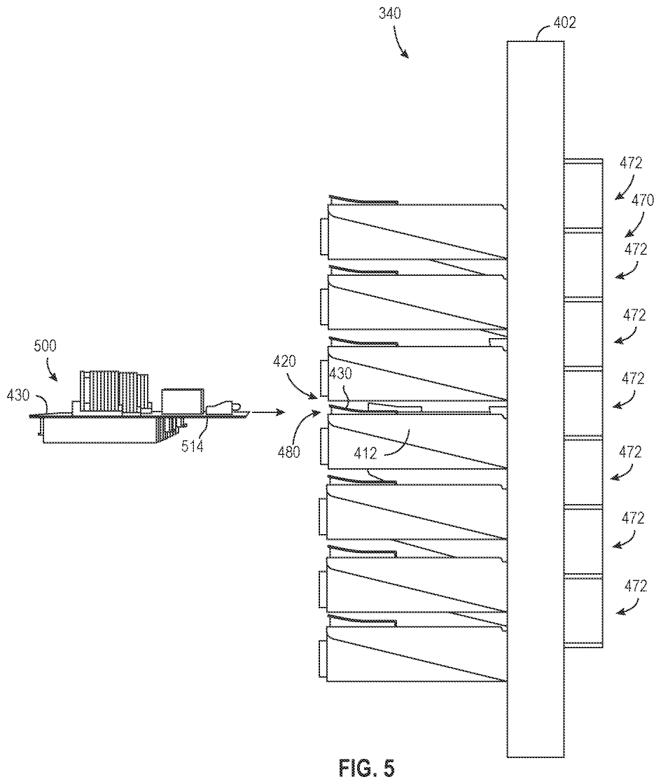

The circuit board guides 430 include an inner wall that defines a circuit board slot 480 configured to receive the chassis-less circuit board substrate of a sled 500 when the sled 500 is received in the corresponding sled slot 420 of the rack 340. To do so, as shown in FIG. 5, a user (or robot) aligns the chassis-less circuit board substrate of an illustrative chassis-less sled 500 to a sled slot 420. The user, or robot, may then slide the chassis-less circuit board substrate forward into the sled slot 420 such that each side edge 514 of the chassis-less circuit board substrate is received in a corresponding circuit board slot 480 of the circuit board guides 430 of the pair 410 of elongated support arms 412 that define the corresponding sled slot 420 as shown in FIG. 5. By having robotically accessible and robotically manipulable sleds including disaggregated resources, the different types of resource can be upgraded independently of one other and at their own optimized refresh rate. Furthermore, the sleds are configured to blindly mate with power and data communication cables in the rack 340, enhancing their ability to be quickly removed, upgraded, reinstalled, and/or replaced. As such, in some examples, the data center 200 may operate (e.g., execute workloads, undergo maintenance and/or upgrades, etc.) without human involvement on the data center floor. In other examples, a human may facilitate one or more maintenance or upgrade operations in the data center 200.

It should be appreciated that the circuit board guides 430 are dual sided. That is, a circuit board guide 430 includes an inner wall that defines a circuit board slot 480 on each side of the circuit board guide 430. In this way, the circuit board guide 430 can support a chassis-less circuit board substrate on either side. As such, a single additional elongated support post may be added to the rack 340 to turn the rack 340 into a two-rack solution that can hold twice as many sled slots 420 as shown in FIG. 4. The illustrative rack 340 includes seven pairs 410 of elongated support arms 412 that define seven corresponding sled slots 420. The sled slots 420 are configured to receive and support a corresponding sled 500 as discussed above. In other examples, the rack 340 may include additional or fewer pairs 410 of elongated support arms 412 (i.e., additional or fewer sled slots 420). It should be appreciated that because the sled 500 is chassis-less, the sled 500 may have an overall height that is different than typical servers. As such, in some examples, the height of a given sled slot 420 may be shorter than the height of a typical server (e.g., shorter than a single rank unit, referred to as “1U”). That is, the vertical distance between pairs 410 of elongated support arms 412 may be less than a standard rack unit “1U.” Additionally, due to the relative decrease in height of the sled slots 420, the overall height of the rack 340 in some examples may be shorter than the height of traditional rack enclosures. For example, in some examples, the elongated support posts 402, 404 may have a length of six feet or less. Again, in other examples, the rack 340 may have different dimensions. For example, in some examples, the vertical distance between pairs 410 of elongated support arms 412 may be greater than a standard rack unit “1U”. In such examples, the increased vertical distance between the sleds allows for larger heatsinks to be attached to the physical resources and for larger fans to be used (e.g., in the fan array 470 described below) for cooling the sleds, which in turn can allow the physical resources to operate at increased power levels. Further, it should be appreciated that the rack 340 does not include any walls, enclosures, or the like. Rather, the rack 340 is an enclosure-less rack that is opened to the local environment. Of course, in some cases, an end plate may be attached to one of the elongated support posts 402, 404 in those situations in which the rack 340 forms an end-of-row rack in the data center 200.

In some examples, various interconnects may be routed upwardly or downwardly through the elongated support posts 402, 404. To facilitate such routing, the elongated support posts 402, 404 include an inner wall that defines an inner chamber in which interconnects may be located. The interconnects routed through the elongated support posts 402, 404 may be implemented as any type of interconnects including, but not limited to, data or communication interconnects to provide communication connections to the sled slots 420, power interconnects to provide power to the sled slots 420, and/or other types of interconnects.

The rack 340, in the illustrative example, includes a support platform on which a corresponding optical data connector (not shown) is mounted. Such optical data connectors are associated with corresponding sled slots 420 and are configured to mate with optical data connectors of corresponding sleds 500 when the sleds 500 are received in the corresponding sled slots 420. In some examples, optical connections between components (e.g., sleds, racks, and switches) in the data center 200 are made with a blind mate optical connection. For example, a door on a given cable may prevent dust from contaminating the fiber inside the cable. In the process of connecting to a blind mate optical connector mechanism, the door is pushed open when the end of the cable approaches or enters the connector mechanism. Subsequently, the optical fiber inside the cable may enter a gel within the connector mechanism and the optical fiber of one cable comes into contact with the optical fiber of another cable within the gel inside the connector mechanism.

The illustrative rack 340 also includes a fan array 470 coupled to the cross-support arms of the rack 340. The fan array 470 includes one or more rows of cooling fans 472, which are aligned in a horizontal line between the elongated support posts 402, 404. In the illustrative example, the fan array 470 includes a row of cooling fans 472 for the different sled slots 420 of the rack 340. As discussed above, the sleds 500 do not include any on-board cooling system in the illustrative example and, as such, the fan array 470 provides cooling for such sleds 500 received in the rack 340. In other examples, some or all of the sleds 500 can include on-board cooling systems. Further, in some examples, the sleds 500 and/or the racks 340 may include and/or incorporate a liquid and/or immersion cooling system to facilitate cooling of electronic component(s) on the sleds 500. The rack 340, in the illustrative example, also includes different power supplies associated with different ones of the sled slots 420. A given power supply is secured to one of the elongated support arms 412 of the pair 410 of elongated support arms 412 that define the corresponding sled slot 420. For example, the rack 340 may include a power supply coupled or secured to individual ones of the elongated support arms 412 extending from the elongated support post 402. A given power supply includes a power connector configured to mate with a power connector of a sled 500 when the sled 500 is received in the corresponding sled slot 420. In the illustrative example, the sled 500 does not include any on-board power supply and, as such, the power supplies provided in the rack 340 supply power to corresponding sleds 500 when mounted to the rack 340. A given power supply is configured to satisfy the power requirements for its associated sled, which can differ from sled to sled. Additionally, the power supplies provided in the rack 340 can operate independent of each other. That is, within a single rack, a first power supply providing power to a compute sled can provide power levels that are different than power levels supplied by a second power supply providing power to an accelerator sled. The power supplies may be controllable at the sled level or rack level, and may be controlled locally by components on the associated sled or remotely, such as by another sled or an orchestrator.

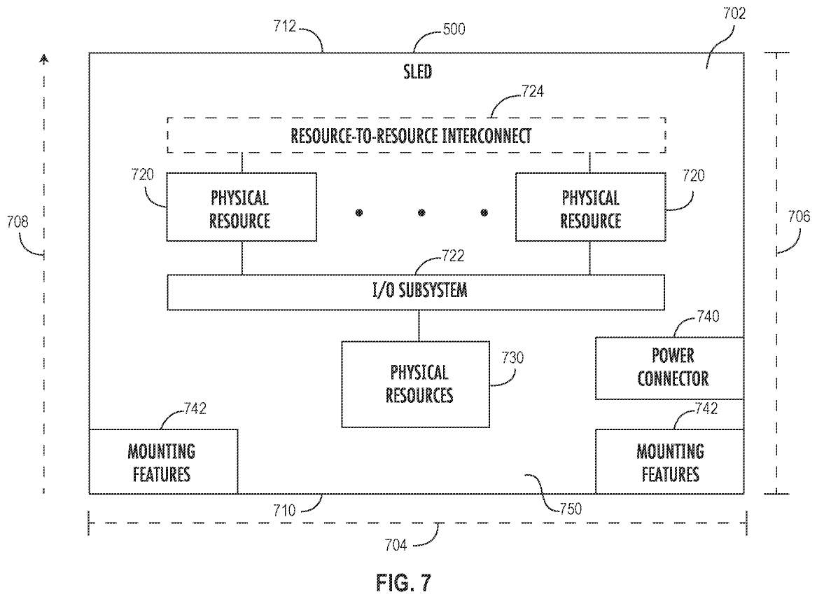

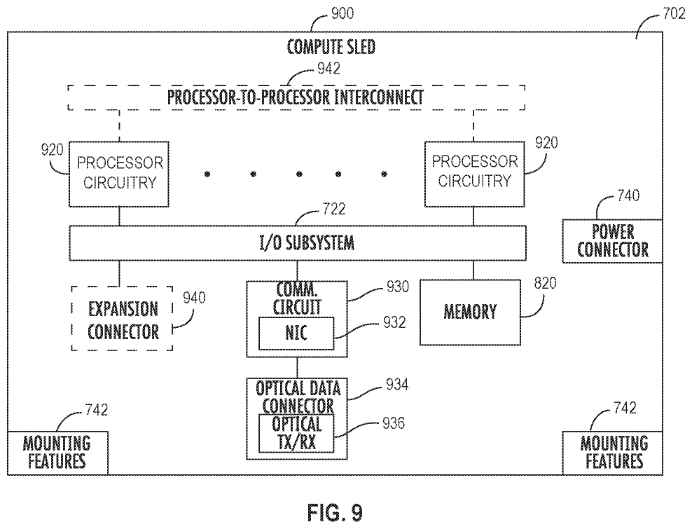

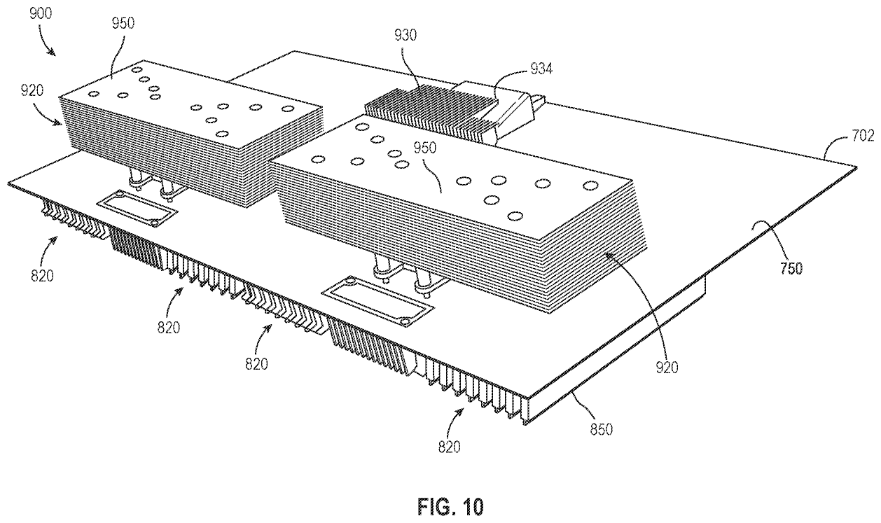

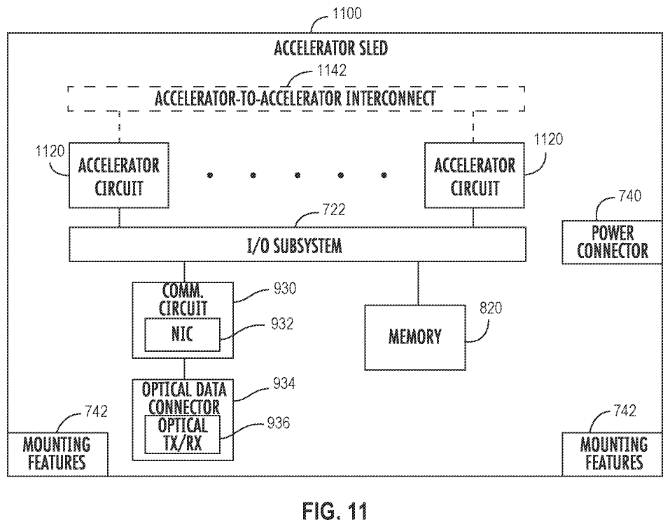

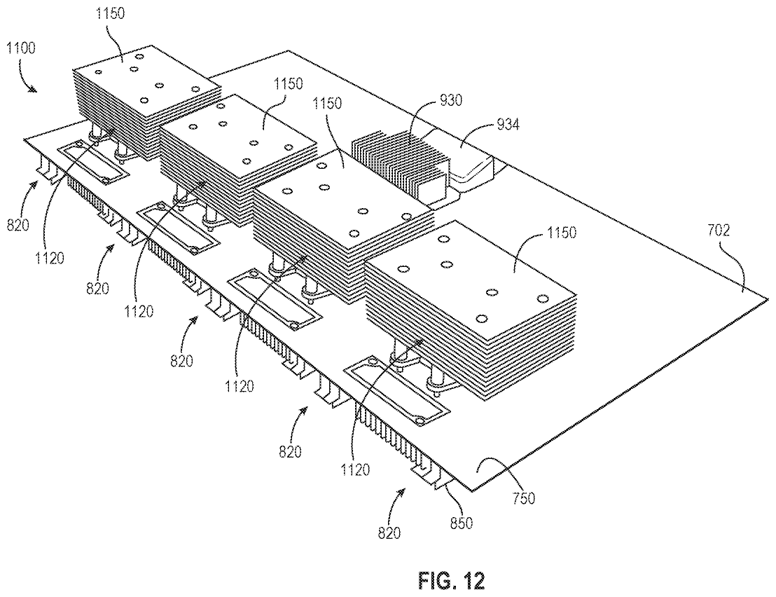

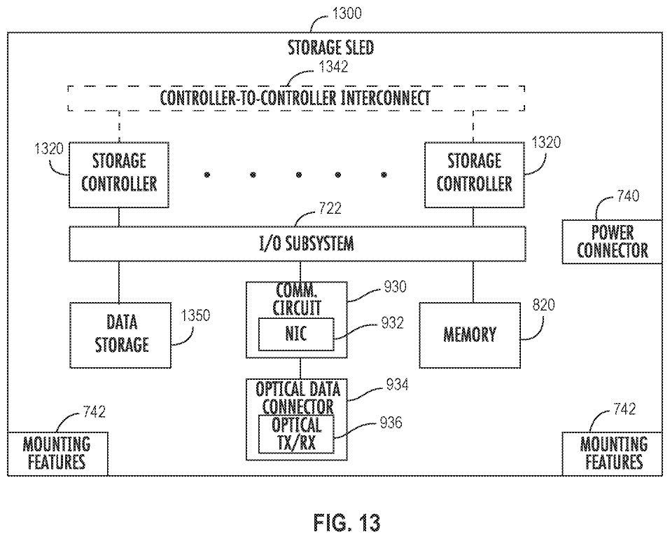

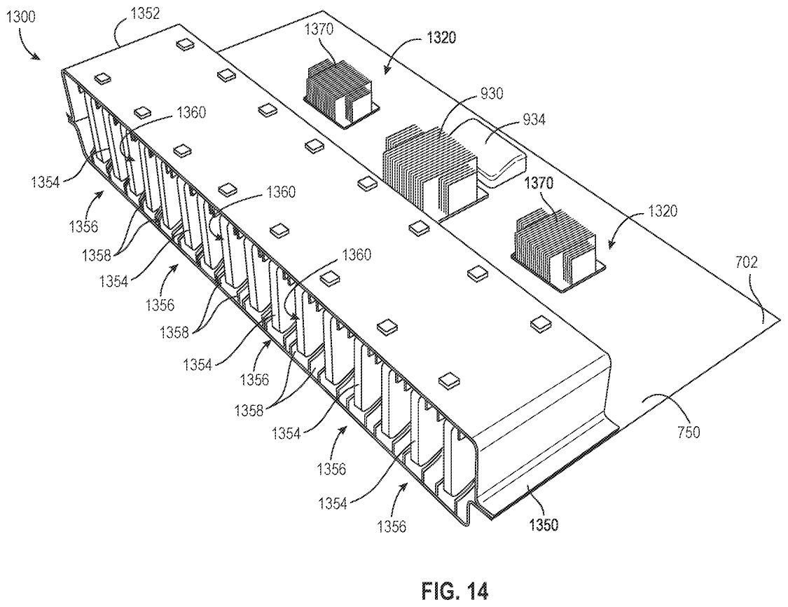

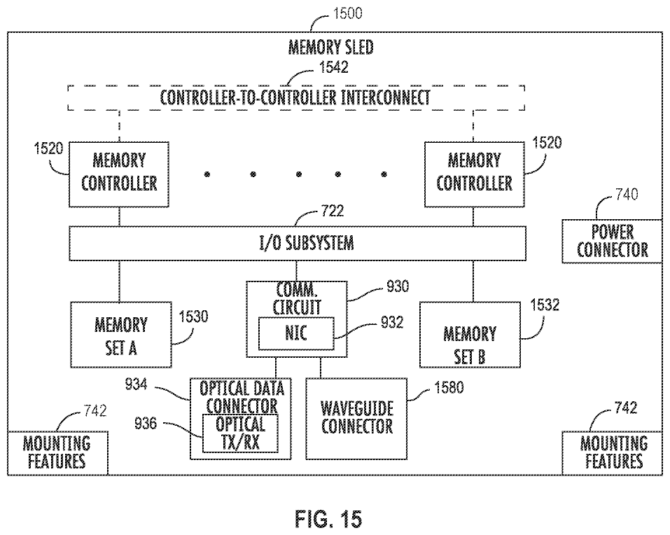

Referring now to FIG. 7, the sled 500, in the illustrative example, is configured to be mounted in a corresponding rack 340 of the data center 200 as discussed above. In some examples, a give sled 500 may be optimized or otherwise configured for performing particular tasks, such as compute tasks, acceleration tasks, data storage tasks, etc. For example, the sled 500 may be implemented as a compute sled 900 as discussed below in regard to FIGS. 9 and 10, an accelerator sled 1100 as discussed below in regard to FIGS. 11 and 12, a storage sled 1300 as discussed below in regard to FIGS. 13 and 14, or as a sled optimized or otherwise configured to perform other specialized tasks, such as a memory sled 1500, discussed below in regard to FIG. 15.

As discussed above, the illustrative sled 500 includes a chassis-less circuit board substrate 702, which supports various physical resources (e.g., electrical components) mounted thereon. It should be appreciated that the circuit board substrate 702 is “chassis-less” in that the sled 500 does not include a housing or enclosure. Rather, the chassis-less circuit board substrate 702 is open to the local environment. The chassis-less circuit board substrate 702 may be formed from any material capable of supporting the various electrical components mounted thereon. For example, in an illustrative example, the chassis-less circuit board substrate 702 is formed from an FR-4 glass-reinforced epoxy laminate material. Of course, other materials may be used to form the chassis-less circuit board substrate 702 in other examples.

As discussed in more detail below, the chassis-less circuit board substrate 702 includes multiple features that improve the thermal cooling characteristics of the various electrical components mounted on the chassis-less circuit board substrate 702. As discussed, the chassis-less circuit board substrate 702 does not include a housing or enclosure, which may improve the airflow over the electrical components of the sled 500 by reducing those structures that may inhibit air flow. For example, because the chassis-less circuit board substrate 702 is not positioned in an individual housing or enclosure, there is no vertically-arranged backplane (e.g., a back plate of the chassis) attached to the chassis-less circuit board substrate 702, which could inhibit air flow across the electrical components. Additionally, the chassis-less circuit board substrate 702 has a geometric shape configured to reduce the length of the airflow path across the electrical components mounted to the chassis-less circuit board substrate 702. For example, the illustrative chassis-less circuit board substrate 702 has a width 704 that is greater than a depth 706 of the chassis-less circuit board substrate 702. In one particular example, the chassis-less circuit board substrate 702 has a width of about 21 inches and a depth of about 9 inches, compared to a typical server that has a width of about 17 inches and a depth of about 39 inches. As such, an airflow path 708 that extends from a front edge 710 of the chassis-less circuit board substrate 702 toward a rear edge 712 has a shorter distance relative to typical servers, which may improve the thermal cooling characteristics of the sled 500. Furthermore, although not illustrated in FIG. 7, the various physical resources mounted to the chassis-less circuit board substrate 702 in this example are mounted in corresponding locations such that no two substantively heat-producing electrical components shadow each other as discussed in more detail below. That is, no two electrical components, which produce appreciable heat during operation (i.e., greater than a nominal heat sufficient enough to adversely impact the cooling of another electrical component), are mounted to the chassis-less circuit board substrate 702 linearly in-line with each other along the direction of the airflow path 708 (i.e., along a direction extending from the front edge 710 toward the rear edge 712 of the chassis-less circuit board substrate 702). The placement and/or structure of the features may be suitable adapted when the electrical component(s) are being cooled via liquid (e.g., one phase or two phase immersion cooling).

As discussed above, the illustrative sled 500 includes one or more physical resources 720 mounted to a top side 750 of the chassis-less circuit board substrate 702. Although two physical resources 720 are shown in FIG. 7, it should be appreciated that the sled 500 may include one, two, or more physical resources 720 in other examples. The physical resources 720 may be implemented as any type of processor, controller, or other compute circuit capable of performing various tasks such as compute functions and/or controlling the functions of the sled 500 depending on, for example, the type or intended functionality of the sled 500. For example, as discussed in more detail below, the physical resources 720 may be implemented as high-performance processors in examples in which the sled 500 is implemented as a compute sled, as accelerator co-processors or circuits in examples in which the sled 500 is implemented as an accelerator sled, storage controllers in examples in which the sled 500 is implemented as a storage sled, or a set of memory devices in examples in which the sled 500 is implemented as a memory sled.

The sled 500 also includes one or more additional physical resources 730 mounted to the top side 750 of the chassis-less circuit board substrate 702. In the illustrative example, the additional physical resources include a network interface controller (NIC) as discussed in more detail below. Of course, depending on the type and functionality of the sled 500, the physical resources 730 may include additional or other electrical components, circuits, and/or devices in other examples.

The physical resources 720 are communicatively coupled to the physical resources 730 via an input/output (I/O) subsystem 722. The I/O subsystem 722 may be implemented as circuitry and/or components to facilitate input/output operations with the physical resources 720, the physical resources 730, and/or other components of the sled 500. For example, the I/O subsystem 722 may be implemented as, or otherwise include, memory controller hubs, input/output control hubs, integrated sensor hubs, firmware devices, communication links (e.g., point-to-point links, bus links, wires, cables, waveguides, light guides, printed circuit board traces, etc.), and/or other components and subsystems to facilitate the input/output operations. In the illustrative example, the I/O subsystem 722 is implemented as, or otherwise includes, a double data rate 4 (DDR4) data bus or a DDR5 data bus.

In some examples, the sled 500 may also include a resource-to-resource interconnect 724. The resource-to-resource interconnect 724 may be implemented as any type of communication interconnect capable of facilitating resource-to-resource communications. In the illustrative example, the resource-to-resource interconnect 724 is implemented as a high-speed point-to-point interconnect (e.g., faster than the I/O subsystem 722). For example, the resource-to-resource interconnect 724 may be implemented as a QuickPath Interconnect (QPI), an UltraPath Interconnect (UPI), or other high-speed point-to-point interconnect dedicated to resource-to-resource communications.

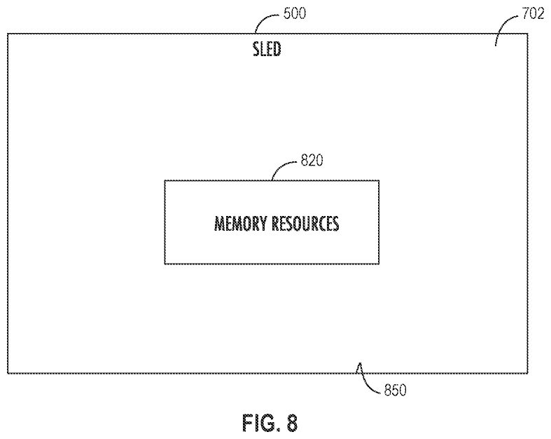

The sled 500 also includes a power connector 740 configured to mate with a corresponding power connector of the rack 340 when the sled 500 is mounted in the corresponding rack 340. The sled 500 receives power from a power supply of the rack 340 via the power connector 740 to supply power to the various electrical components of the sled 500. That is, the sled 500 does not include any local power supply (i.e., an on-board power supply) to provide power to the electrical components of the sled 500. The exclusion of a local or on-board power supply facilitates the reduction in the overall footprint of the chassis-less circuit board substrate 702, which may increase the thermal cooling characteristics of the various electrical components mounted on the chassis-less circuit board substrate 702 as discussed above. In some examples, voltage regulators are placed on a bottom side 850 (see FIG. 8) of the chassis-less circuit board substrate 702 directly opposite of processor circuitry 920 (see FIG. 9), and power is routed from the voltage regulators to the processor circuitry 920 by vias extending through the circuit board substrate 702. Such a configuration provides an increased thermal budget, additional current and/or voltage, and better voltage control relative to typical printed circuit boards in which processor power is delivered from a voltage regulator, in part, by printed circuit traces.

In some examples, the sled 500 may also include mounting features 742 configured to mate with a mounting arm, or other structure, of a robot to facilitate the placement of the sled 700 in a rack 340 by the robot. The mounting features 742 may be implemented as any type of physical structures that allow the robot to grasp the sled 500 without damaging the chassis-less circuit board substrate 702 or the electrical components mounted thereto. For example, in some examples, the mounting features 742 may be implemented as non-conductive pads attached to the chassis-less circuit board substrate 702. In other examples, the mounting features may be implemented as brackets, braces, or other similar structures attached to the chassis-less circuit board substrate 702. The particular number, shape, size, and/or make-up of the mounting feature 742 may depend on the design of the robot configured to manage the sled 500.

Referring now to FIG. 8, in addition to the physical resources 730 mounted on the top side 750 of the chassis-less circuit board substrate 702, the sled 500 also includes one or more memory devices 820 mounted to a bottom side 850 of the chassis-less circuit board substrate 702. That is, the chassis-less circuit board substrate 702 is implemented as a double-sided circuit board. The physical resources 720 are communicatively coupled to the memory devices 820 via the I/O subsystem 722. For example, the physical resources 720 and the memory devices 820 may be communicatively coupled by one or more vias extending through the chassis-less circuit board substrate 702. Different ones of the physical resources 720 may be communicatively coupled to different sets of one or more memory devices 820 in some examples. Alternatively, in other examples, different ones of the physical resources 720 may be communicatively coupled to the same ones of the memory devices 820.

The memory devices 820 may be implemented as any type of memory device capable of storing data for the physical resources 720 during operation of the sled 500, such as any type of volatile (e.g., dynamic random access memory (DRAM), etc.) or non-volatile memory. Volatile memory may be a storage medium that requires power to maintain the state of data stored by the medium. Non-limiting examples of volatile memory may include various types of random access memory (RAM), such as dynamic random access memory (DRAM) or static random access memory (SRAM). One particular type of DRAM that may be used in a memory module is synchronous dynamic random access memory (SDRAM). In particular examples, DRAM of a memory component may comply with a standard promulgated by JEDEC, such as JESD79F for DDR SDRAM, JESD79-2F for DDR2 SDRAM, JESD79-3F for DDR3 SDRAM, JESD79-4A for DDR4 SDRAM, JESD209 for Low Power DDR (LPDDR), JESD209-2 for LPDDR2, JESD209-3 for LPDDR3, and JESD209-4 for LPDDR4. Such standards (and similar standards) may be referred to as DDR-based standards and communication interfaces of the storage devices that implement such standards may be referred to as DDR-based interfaces.

In one example, the memory device is a block addressable memory device, such as those based on NAND or NOR technologies. A memory device may also include next-generation nonvolatile devices, such as Intel 3D XPoint™ memory or other byte addressable write-in-place nonvolatile memory devices. In one example, the memory device may be or may include memory devices that use chalcogenide glass, multi-threshold level NAND flash memory, NOR flash memory, single or multi-level Phase Change Memory (PCM), a resistive memory, nanowire memory, ferroelectric transistor random access memory (FeTRAM), anti-ferroelectric memory, magnetoresistive random access memory (MRAM) memory that incorporates memristor technology, resistive memory including the metal oxide base, the oxygen vacancy base and the conductive bridge Random Access Memory (CB-RAM), or spin transfer torque (STT)-MRAM, a spintronic magnetic junction memory based device, a magnetic tunneling junction (MTJ) based device, a DW (Domain Wall) and SOT (Spin Orbit Transfer) based device, a thyristor based memory device, or a combination of any of the above, or other memory. The memory device may refer to the die itself and/or to a packaged memory product. In some examples, the memory device may include a transistor-less stackable cross point architecture in which memory cells sit at the intersection of word lines and bit lines and are individually addressable and in which bit storage is based on a change in bulk resistance.

Referring now to FIG. 9, in some examples, the sled 500 may be implemented as a compute sled 900. The compute sled 900 is optimized, or otherwise configured, to perform compute tasks. Of course, as discussed above, the compute sled 900 may rely on other sleds, such as acceleration sleds and/or storage sleds, to perform such compute tasks. The compute sled 900 includes various physical resources (e.g., electrical components) similar to the physical resources of the sled 500, which have been identified in FIG. 9 using the same reference numbers. The description of such components provided above in regard to FIGS. 7 and 8 applies to the corresponding components of the compute sled 900 and is not repeated herein for clarity of the description of the compute sled 900.

In the illustrative compute sled 900, the physical resources 720 include processor circuitry 920. Although only two blocks of processor circuitry 920 are shown in FIG. 9, it should be appreciated that the compute sled 900 may include additional processor circuits 920 in other examples. Illustratively, the processor circuitry 920 corresponds to high-performance processors 920 and may be configured to operate at a relatively high power rating. Although the high-performance processor circuitry 920 generates additional heat operating at power ratings greater than typical processors (which operate at around 155-230 W), the enhanced thermal cooling characteristics of the chassis-less circuit board substrate 702 discussed above facilitate the higher power operation. For example, in the illustrative example, the processor circuitry 920 is configured to operate at a power rating of at least 250 W. In some examples, the processor circuitry 920 may be configured to operate at a power rating of at least 350 W.

In some examples, the compute sled 900 may also include a processor-to-processor interconnect 942. Similar to the resource-to-resource interconnect 724 of the sled 500 discussed above, the processor-to-processor interconnect 942 may be implemented as any type of communication interconnect capable of facilitating processor-to-processor interconnect 942 communications. In the illustrative example, the processor-to-processor interconnect 942 is implemented as a high-speed point-to-point interconnect (e.g., faster than the I/O subsystem 722). For example, the processor-to-processor interconnect 942 may be implemented as a QuickPath Interconnect (QPI), an UltraPath Interconnect (UPI), or other high-speed point-to-point interconnect dedicated to processor-to-processor communications.

The compute sled 900 also includes a communication circuit 930. The illustrative communication circuit 930 includes a network interface controller (NIC) 932, which may also be referred to as a host fabric interface (HFI). The NIC 932 may be implemented as, or otherwise include, any type of integrated circuit, discrete circuits, controller chips, chipsets, add-in-boards, daughtercards, network interface cards, or other devices that may be used by the compute sled 900 to connect with another compute device (e.g., with other sleds 500). In some examples, the NIC 932 may be implemented as part of a system-on-a-chip (SoC) that includes one or more processors, or included on a multichip package that also contains one or more processors. In some examples, the NIC 932 may include a local processor (not shown) and/or a local memory (not shown) that are both local to the NIC 932. In such examples, the local processor of the NIC 932 may be capable of performing one or more of the functions of the processor circuitry 920. Additionally or alternatively, in such examples, the local memory of the NIC 932 may be integrated into one or more components of the compute sled at the board level, socket level, chip level, and/or other levels.

The communication circuit 930 is communicatively coupled to an optical data connector 934. The optical data connector 934 is configured to mate with a corresponding optical data connector of the rack 340 when the compute sled 900 is mounted in the rack 340. Illustratively, the optical data connector 934 includes a plurality of optical fibers which lead from a mating surface of the optical data connector 934 to an optical transceiver 936. The optical transceiver 936 is configured to convert incoming optical signals from the rack-side optical data connector to electrical signals and to convert electrical signals to outgoing optical signals to the rack-side optical data connector. Although shown as forming part of the optical data connector 934 in the illustrative example, the optical transceiver 936 may form a portion of the communication circuit 930 in other examples.

In some examples, the compute sled 900 may also include an expansion connector 940. In such examples, the expansion connector 940 is configured to mate with a corresponding connector of an expansion chassis-less circuit board substrate to provide additional physical resources to the compute sled 900. The additional physical resources may be used, for example, by the processor circuitry 920 during operation of the compute sled 900. The expansion chassis-less circuit board substrate may be substantially similar to the chassis-less circuit board substrate 702 discussed above and may include various electrical components mounted thereto. The particular electrical components mounted to the expansion chassis-less circuit board substrate may depend on the intended functionality of the expansion chassis-less circuit board substrate. For example, the expansion chassis-less circuit board substrate may provide additional compute resources, memory resources, and/or storage resources. As such, the additional physical resources of the expansion chassis-less circuit board substrate may include, but is not limited to, processors, memory devices, storage devices, and/or accelerator circuits including, for example, field programmable gate arrays (FPGA), application-specific integrated circuits (ASICs), security co-processors, graphics processing units (GPUs), machine learning circuits, or other specialized processors, controllers, devices, and/or circuits.

Referring now to FIG. 10, an illustrative example of the compute sled 900 is shown. As shown, the processor circuitry 920, communication circuit 930, and optical data connector 934 are mounted to the top side 750 of the chassis-less circuit board substrate 702. Any suitable attachment or mounting technology may be used to mount the physical resources of the compute sled 900 to the chassis-less circuit board substrate 702. For example, the various physical resources may be mounted in corresponding sockets (e.g., a processor socket), holders, or brackets. In some cases, some of the electrical components may be directly mounted to the chassis-less circuit board substrate 702 via soldering or similar techniques.

As discussed above, the separate processor circuitry 920 and the communication circuit 930 are mounted to the top side 750 of the chassis-less circuit board substrate 702 such that no two heat-producing, electrical components shadow each other. In the illustrative example, the processor circuitry 920 and the communication circuit 930 are mounted in corresponding locations on the top side 750 of the chassis-less circuit board substrate 702 such that no two of those physical resources are linearly in-line with others along the direction of the airflow path 708. It should be appreciated that, although the optical data connector 934 is in-line with the communication circuit 930, the optical data connector 934 produces no or nominal heat during operation.

The memory devices 820 of the compute sled 900 are mounted to the bottom side 850 of the of the chassis-less circuit board substrate 702 as discussed above in regard to the sled 500. Although mounted to the bottom side 850, the memory devices 820 are communicatively coupled to the processor circuitry 920 located on the top side 750 via the I/O subsystem 722. Because the chassis-less circuit board substrate 702 is implemented as a double-sided circuit board, the memory devices 820 and the processor circuitry 920 may be communicatively coupled by one or more vias, connectors, or other mechanisms extending through the chassis-less circuit board substrate 702. Of course, different processor circuitry 920 (e.g., different processors) may be communicatively coupled to a different set of one or more memory devices 820 in some examples. Alternatively, in other examples, different processor circuitry 920 (e.g., different processors) may be communicatively coupled to the same ones of the memory devices 820. In some examples, the memory devices 820 may be mounted to one or more memory mezzanines on the bottom side of the chassis-less circuit board substrate 702 and may interconnect with a corresponding processor circuitry 920 through a ball-grid array.

Different processor circuitry 920 (e.g., different processors) include and/or is associated with corresponding heatsinks 950 secured thereto. Due to the mounting of the memory devices 820 to the bottom side 850 of the chassis-less circuit board substrate 702 (as well as the vertical spacing of the sleds 500 in the corresponding rack 340), the top side 750 of the chassis-less circuit board substrate 702 includes additional “free” area or space that facilitates the use of heatsinks 950 having a larger size relative to traditional heatsinks used in typical servers. Additionally, due to the improved thermal cooling characteristics of the chassis-less circuit board substrate 702, none of the processor heatsinks 950 include cooling fans attached thereto. That is, the heatsinks 950 may be fan-less heatsinks. In some examples, the heatsinks 950 mounted atop the processor circuitry 920 may overlap with the heatsink attached to the communication circuit 930 in the direction of the airflow path 708 due to their increased size, as illustratively suggested by FIG. 10.

Referring now to FIG. 11, in some examples, the sled 500 may be implemented as an accelerator sled 1100. The accelerator sled 1100 is configured, to perform specialized compute tasks, such as machine learning, encryption, hashing, or other computational-intensive task. In some examples, for example, a compute sled 900 may offload tasks to the accelerator sled 1100 during operation. The accelerator sled 1100 includes various components similar to components of the sled 500 and/or the compute sled 900, which have been identified in FIG. 11 using the same reference numbers. The description of such components provided above in regard to FIGS. 7, 8, and 9 apply to the corresponding components of the accelerator sled 1100 and is not repeated herein for clarity of the description of the accelerator sled 1100.

In the illustrative accelerator sled 1100, the physical resources 720 include accelerator circuits 1120. Although only two accelerator circuits 1120 are shown in FIG. 11, it should be appreciated that the accelerator sled 1100 may include additional accelerator circuits 1120 in other examples. For example, as shown in FIG. 12, the accelerator sled 1100 may include four accelerator circuits 1120. The accelerator circuits 1120 may be implemented as any type of processor, co-processor, compute circuit, or other device capable of performing compute or processing operations. For example, the accelerator circuits 1120 may be implemented as, for example, field programmable gate arrays (FPGA), application-specific integrated circuits (ASICs), security co-processors, graphics processing units (GPUs), neuromorphic processor units, quantum computers, machine learning circuits, or other specialized processors, controllers, devices, and/or circuits.

In some examples, the accelerator sled 1100 may also include an accelerator-to-accelerator interconnect 1142. Similar to the resource-to-resource interconnect 724 of the sled 700 discussed above, the accelerator-to-accelerator interconnect 1142 may be implemented as any type of communication interconnect capable of facilitating accelerator-to-accelerator communications. In the illustrative example, the accelerator-to-accelerator interconnect 1142 is implemented as a high-speed point-to-point interconnect (e.g., faster than the I/O subsystem 722). For example, the accelerator-to-accelerator interconnect 1142 may be implemented as a QuickPath Interconnect (QPI), an UltraPath Interconnect (UPI), or other high-speed point-to-point interconnect dedicated to processor-to-processor communications. In some examples, the accelerator circuits 1120 may be daisy-chained with a primary accelerator circuit 1120 connected to the NIC 932 and memory 820 through the I/O subsystem 722 and a secondary accelerator circuit 1120 connected to the NIC 932 and memory 820 through a primary accelerator circuit 1120.

Referring now to FIG. 12, an illustrative example of the accelerator sled 1100 is shown. As discussed above, the accelerator circuits 1120, the communication circuit 930, and the optical data connector 934 are mounted to the top side 750 of the chassis-less circuit board substrate 702. Again, the individual accelerator circuits 1120 and communication circuit 930 are mounted to the top side 750 of the chassis-less circuit board substrate 702 such that no two heat-producing, electrical components shadow each other as discussed above. The memory devices 820 of the accelerator sled 1100 are mounted to the bottom side 850 of the of the chassis-less circuit board substrate 702 as discussed above in regard to the sled 700. Although mounted to the bottom side 850, the memory devices 820 are communicatively coupled to the accelerator circuits 1120 located on the top side 750 via the I/O subsystem 722 (e.g., through vias). Further, the accelerator circuits 1120 may include and/or be associated with a heatsink 1150 that is larger than a traditional heatsink used in a server. As discussed above with reference to the heatsinks 950 of FIG. 9, the heatsinks 1150 may be larger than traditional heatsinks because of the “free” area provided by the memory resources 820 being located on the bottom side 850 of the chassis-less circuit board substrate 702 rather than on the top side 750.

Referring now to FIG. 13, in some examples, the sled 500 may be implemented as a storage sled 1300. The storage sled 1300 is configured, to store data in a data storage 1350 local to the storage sled 1300. For example, during operation, a compute sled 900 or an accelerator sled 1100 may store and retrieve data from the data storage 1350 of the storage sled 1300. The storage sled 1300 includes various components similar to components of the sled 500 and/or the compute sled 900, which have been identified in FIG. 13 using the same reference numbers. The description of such components provided above in regard to FIGS. 7, 8, and 9 apply to the corresponding components of the storage sled 1300 and is not repeated herein for clarity of the description of the storage sled 1300.

In the illustrative storage sled 1300, the physical resources 720 includes storage controllers 1320. Although only two storage controllers 1320 are shown in FIG. 13, it should be appreciated that the storage sled 1300 may include additional storage controllers 1320 in other examples. The storage controllers 1320 may be implemented as any type of processor, controller, or control circuit capable of controlling the storage and retrieval of data into the data storage 1350 based on requests received via the communication circuit 930. In the illustrative example, the storage controllers 1320 are implemented as relatively low-power processors or controllers. For example, in some examples, the storage controllers 1320 may be configured to operate at a power rating of about 75 watts.

In some examples, the storage sled 1300 may also include a controller-to-controller interconnect 1342. Similar to the resource-to-resource interconnect 724 of the sled 500 discussed above, the controller-to-controller interconnect 1342 may be implemented as any type of communication interconnect capable of facilitating controller-to-controller communications. In the illustrative example, the controller-to-controller interconnect 1342 is implemented as a high-speed point-to-point interconnect (e.g., faster than the I/O subsystem 722). For example, the controller-to-controller interconnect 1342 may be implemented as a QuickPath Interconnect (QPI), an UltraPath Interconnect (UPI), or other high-speed point-to-point interconnect dedicated to processor-to-processor communications.

Referring now to FIG. 14, an illustrative example of the storage sled 1300 is shown. In the illustrative example, the data storage 1350 is implemented as, or otherwise includes, a storage cage 1352 configured to house one or more solid state drives (SSDs) 1354. To do so, the storage cage 1352 includes a number of mounting slots 1356, which are configured to receive corresponding solid state drives 1354. The mounting slots 1356 include a number of drive guides 1358 that cooperate to define an access opening 1360 of the corresponding mounting slot 1356. The storage cage 1352 is secured to the chassis-less circuit board substrate 702 such that the access openings face away from (i.e., toward the front of) the chassis-less circuit board substrate 702. As such, solid state drives 1354 are accessible while the storage sled 1300 is mounted in a corresponding rack 304. For example, a solid state drive 1354 may be swapped out of a rack 340 (e.g., via a robot) while the storage sled 1300 remains mounted in the corresponding rack 340.

The storage cage 1352 illustratively includes sixteen mounting slots 1356 and is capable of mounting and storing sixteen solid state drives 1354. Of course, the storage cage 1352 may be configured to store additional or fewer solid state drives 1354 in other examples. Additionally, in the illustrative example, the solid state drives are mounted vertically in the storage cage 1352, but may be mounted in the storage cage 1352 in a different orientation in other examples. A given solid state drive 1354 may be implemented as any type of data storage device capable of storing long term data. To do so, the solid state drives 1354 may include volatile and non-volatile memory devices discussed above.

As shown in FIG. 14, the storage controllers 1320, the communication circuit 930, and the optical data connector 934 are illustratively mounted to the top side 750 of the chassis-less circuit board substrate 702. Again, as discussed above, any suitable attachment or mounting technology may be used to mount the electrical components of the storage sled 1300 to the chassis-less circuit board substrate 702 including, for example, sockets (e.g., a processor socket), holders, brackets, soldered connections, and/or other mounting or securing techniques.

As discussed above, the individual storage controllers 1320 and the communication circuit 930 are mounted to the top side 750 of the chassis-less circuit board substrate 702 such that no two heat-producing, electrical components shadow each other. For example, the storage controllers 1320 and the communication circuit 930 are mounted in corresponding locations on the top side 750 of the chassis-less circuit board substrate 702 such that no two of those electrical components are linearly in-line with each other along the direction of the airflow path 708.

The memory devices 820 (not shown in FIG. 14) of the storage sled 1300 are mounted to the bottom side 850 (not shown in FIG. 14) of the chassis-less circuit board substrate 702 as discussed above in regard to the sled 500. Although mounted to the bottom side 850, the memory devices 820 are communicatively coupled to the storage controllers 1320 located on the top side 750 via the I/O subsystem 722. Again, because the chassis-less circuit board substrate 702 is implemented as a double-sided circuit board, the memory devices 820 and the storage controllers 1320 may be communicatively coupled by one or more vias, connectors, or other mechanisms extending through the chassis-less circuit board substrate 702. The storage controllers 1320 include and/or are associated with a heatsink 1370 secured thereto. As discussed above, due to the improved thermal cooling characteristics of the chassis-less circuit board substrate 702 of the storage sled 1300, none of the heatsinks 1370 include cooling fans attached thereto. That is, the heatsinks 1370 may be fan-less heatsinks.

Referring now to FIG. 15, in some examples, the sled 500 may be implemented as a memory sled 1500. The storage sled 1500 is optimized, or otherwise configured, to provide other sleds 500 (e.g., compute sleds 900, accelerator sleds 1100, etc.) with access to a pool of memory (e.g., in two or more sets 1530, 1532 of memory devices 820) local to the memory sled 1300. For example, during operation, a compute sled 900 or an accelerator sled 1100 may remotely write to and/or read from one or more of the memory sets 1530, 1532 of the memory sled 1300 using a logical address space that maps to physical addresses in the memory sets 1530, 1532. The memory sled 1500 includes various components similar to components of the sled 500 and/or the compute sled 900, which have been identified in FIG. 15 using the same reference numbers. The description of such components provided above in regard to FIGS. 7, 8, and 9 apply to the corresponding components of the memory sled 1500 and is not repeated herein for clarity of the description of the memory sled 1500.

In the illustrative memory sled 1500, the physical resources 720 include memory controllers 1520. Although only two memory controllers 1520 are shown in FIG. 15, it should be appreciated that the memory sled 1500 may include additional memory controllers 1520 in other examples. The memory controllers 1520 may be implemented as any type of processor, controller, or control circuit capable of controlling the writing and reading of data into the memory sets 1530, 1532 based on requests received via the communication circuit 930. In the illustrative example, the memory controllers 1520 are connected to corresponding memory sets 1530, 1532 to write to and read from memory devices 820 (not shown) within the corresponding memory set 1530, 1532 and enforce any permissions (e.g., read, write, etc.) associated with sled 500 that has sent a request to the memory sled 1500 to perform a memory access operation (e.g., read or write).

In some examples, the memory sled 1500 may also include a controller-to-controller interconnect 1542. Similar to the resource-to-resource interconnect 724 of the sled 500 discussed above, the controller-to-controller interconnect 1542 may be implemented as any type of communication interconnect capable of facilitating controller-to-controller communications. In the illustrative example, the controller-to-controller interconnect 1542 is implemented as a high-speed point-to-point interconnect (e.g., faster than the I/O subsystem 722). For example, the controller-to-controller interconnect 1542 may be implemented as a QuickPath Interconnect (QPI), an UltraPath Interconnect (UPI), or other high-speed point-to-point interconnect dedicated to processor-to-processor communications. As such, in some examples, a memory controller 1520 may access, through the controller-to-controller interconnect 1542, memory that is within the memory set 1532 associated with another memory controller 1520. In some examples, a scalable memory controller is made of multiple smaller memory controllers, referred to herein as “chiplets”, on a memory sled (e.g., the memory sled 1500). The chiplets may be interconnected (e.g., using EMIB (Embedded Multi-Die Interconnect Bridge) technology). The combined chiplet memory controller may scale up to a relatively large number of memory controllers and I/O ports, (e.g., up to 16 memory channels). In some examples, the memory controllers 1520 may implement a memory interleave (e.g., one memory address is mapped to the memory set 1530, the next memory address is mapped to the memory set 1532, and the third address is mapped to the memory set 1530, etc.). The interleaving may be managed within the memory controllers 1520, or from CPU sockets (e.g., of the compute sled 900) across network links to the memory sets 1530, 1532, and may improve the latency associated with performing memory access operations as compared to accessing contiguous memory addresses from the same memory device.

Further, in some examples, the memory sled 1500 may be connected to one or more other sleds 500 (e.g., in the same rack 340 or an adjacent rack 340) through a waveguide, using the waveguide connector 1580. In the illustrative example, the waveguides are 74 millimeter waveguides that provide 16 Rx (i.e., receive) lanes and 16 Tx (i.e., transmit) lanes. Different ones of the lanes, in the illustrative example, are either 16 GHz or 32 GHz. In other examples, the frequencies may be different. Using a waveguide may provide high throughput access to the memory pool (e.g., the memory sets 1530, 1532) to another sled (e.g., a sled 500 in the same rack 340 or an adjacent rack 340 as the memory sled 1500) without adding to the load on the optical data connector 934.

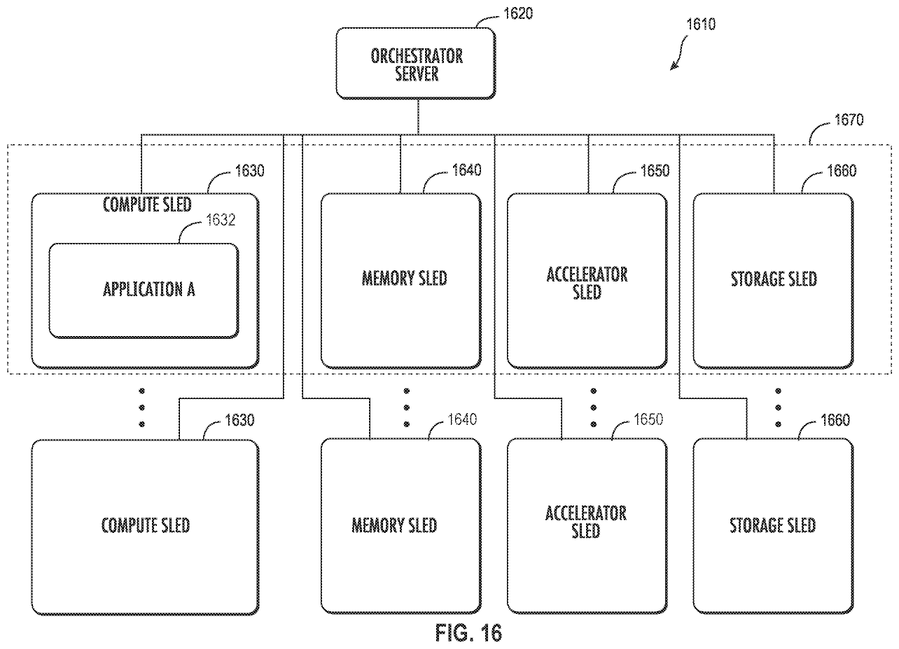

Referring now to FIG. 16, a system for executing one or more workloads (e.g., applications) may be implemented in accordance with the data center 200. In the illustrative example, the system 1610 includes an orchestrator server 1620, which may be implemented as a managed node including a compute device (e.g., processor circuitry 920 on a compute sled 900) executing management software (e.g., a cloud operating environment, such as OpenStack) that is communicatively coupled to multiple sleds 500 including a large number of compute sleds 1630 (e.g., similar to the compute sled 900), memory sleds 1640 (e.g., similar to the memory sled 1500), accelerator sleds 1650 (e.g., similar to the memory sled 1000), and storage sleds 1660 (e.g., similar to the storage sled 1300). One or more of the sleds 1630, 1640, 1650, 1660 may be grouped into a managed node 1670, such as by the orchestrator server 1620, to collectively perform a workload (e.g., an application 1632 executed in a virtual machine or in a container). The managed node 1670 may be implemented as an assembly of physical resources 720, such as processor circuitry 920, memory resources 820, accelerator circuits 1120, or data storage 1350, from the same or different sleds 500. Further, the managed node may be established, defined, or “spun up” by the orchestrator server 1620 at the time a workload is to be assigned to the managed node or at any other time, and may exist regardless of whether any workloads are presently assigned to the managed node. In the illustrative example, the orchestrator server 1620 may selectively allocate and/or deallocate physical resources 720 from the sleds 500 and/or add or remove one or more sleds 500 from the managed node 1670 as a function of quality of service (QoS) targets (e.g., a target throughput, a target latency, a target number of instructions per second, etc.) associated with a service level agreement for the workload (e.g., the application 1632). In doing so, the orchestrator server 1620 may receive telemetry data indicative of performance conditions (e.g., throughput, latency, instructions per second, etc.) in different ones of the sleds 500 of the managed node 1670 and compare the telemetry data to the quality of service targets to determine whether the quality of service targets are being satisfied. The orchestrator server 1620 may additionally determine whether one or more physical resources may be deallocated from the managed node 1670 while still satisfying the QoS targets, thereby freeing up those physical resources for use in another managed node (e.g., to execute a different workload). Alternatively, if the QoS targets are not presently satisfied, the orchestrator server 1620 may determine to dynamically allocate additional physical resources to assist in the execution of the workload (e.g., the application 1632) while the workload is executing. Similarly, the orchestrator server 1620 may determine to dynamically deallocate physical resources from a managed node if the orchestrator server 1620 determines that deallocating the physical resource would result in QoS targets still being met.

Additionally, in some examples, the orchestrator server 1620 may identify trends in the resource utilization of the workload (e.g., the application 1632), such as by identifying phases of execution (e.g., time periods in which different operations, having different resource utilizations characteristics, are performed) of the workload (e.g., the application 1632) and pre-emptively identifying available resources in the data center 200 and allocating them to the managed node 1670 (e.g., within a predefined time period of the associated phase beginning). In some examples, the orchestrator server 1620 may model performance based on various latencies and a distribution scheme to place workloads among compute sleds and other resources (e.g., accelerator sleds, memory sleds, storage sleds) in the data center 200. For example, the orchestrator server 1620 may utilize a model that accounts for the performance of resources on the sleds 500 (e.g., FPGA performance, memory access latency, etc.) and the performance (e.g., congestion, latency, bandwidth) of the path through the network to the resource (e.g., FPGA). As such, the orchestrator server 1620 may determine which resource(s) should be used with which workloads based on the total latency associated with different potential resource(s) available in the data center 200 (e.g., the latency associated with the performance of the resource itself in addition to the latency associated with the path through the network between the compute sled executing the workload and the sled 500 on which the resource is located).

In some examples, the orchestrator server 1620 may generate a map of heat generation in the data center 200 using telemetry data (e.g., temperatures, fan speeds, etc.) reported from the sleds 500 and allocate resources to managed nodes as a function of the map of heat generation and predicted heat generation associated with different workloads, to maintain a target temperature and heat distribution in the data center 200. Additionally or alternatively, in some examples, the orchestrator server 1620 may organize received telemetry data into a hierarchical model that is indicative of a relationship between the managed nodes (e.g., a spatial relationship such as the physical locations of the resources of the managed nodes within the data center 200 and/or a functional relationship, such as groupings of the managed nodes by the customers the managed nodes provide services for, the types of functions typically performed by the managed nodes, managed nodes that typically share or exchange workloads among each other, etc.). Based on differences in the physical locations and resources in the managed nodes, a given workload may exhibit different resource utilizations (e.g., cause a different internal temperature, use a different percentage of processor or memory capacity) across the resources of different managed nodes. The orchestrator server 1620 may determine the differences based on the telemetry data stored in the hierarchical model and factor the differences into a prediction of future resource utilization of a workload if the workload is reassigned from one managed node to another managed node, to accurately balance resource utilization in the data center 200. In some examples, the orchestrator server 1620 may identify patterns in resource utilization phases of the workloads and use the patterns to predict future resource utilization of the workloads.

To reduce the computational load on the orchestrator server 1620 and the data transfer load on the network, in some examples, the orchestrator server 1620 may send self-test information to the sleds 500 to enable a given sled 500 to locally (e.g., on the sled 500) determine whether telemetry data generated by the sled 500 satisfies one or more conditions (e.g., an available capacity that satisfies a predefined threshold, a temperature that satisfies a predefined threshold, etc.). The given sled 500 may then report back a simplified result (e.g., yes or no) to the orchestrator server 1620, which the orchestrator server 1620 may utilize in determining the allocation of resources to managed nodes.

FIG. 17 is an exploded diagram of an integrated circuit heat dissipation component stack 1700 (hereafter referred to as a “component stack”). In FIG. 17, the prior component stack 1700 includes a heatsink 1702, a carrier 1704, a socket 1706, an integrated circuit (IC) package 1708, a bolster plate 1710, a printed circuit board (PCB) 1712, and a back plate 1714. In FIG. 17, a first fastener 1716A, a second fastener 1716B, a third fastener 1716C, and a fourth fastener 1716D serve to provide a compressive force on the components within the component stack 1700.

The IC package 1708 can include one or more electrical circuits on a semiconductor substrate. As used herein, the term “integrated circuit package” refers to the components associated with an integrated circuit including an integrated heat spreader (IHS), a package substrate supporting the integrated circuit, the integrated circuit, etc. The IC package 1708 can perform processing functions, memory functions, and/or any other suitable functions. The IC package 1708 can be implemented by any type of processing circuitry, including programmable microprocessors, one or more FPGAs, one or more CPUs, one or more GPUs, one or more DSPs, one or more XPUs, one or more ASICs, and/or one or more microcontrollers. The IC package 1708 can include a mechanical/electrical interface (e.g., pin cavities, contact lands, etc.) to receive and/or electrically couple with corresponding features (e.g., electrical connectors) of the socket 1706.

The socket 1706 communicatively couples the IC package 1708 to the PCB 1712. In the illustrated example of FIG. 17, the socket 1706 is a land grid array (LGA) socket, which includes a plurality of pins within the socket. The socket 1706 includes a rectangular grid of pins, which interface with corresponding holes on the IC package 1708. If the contact between the pins of the socket 1706 and the integrated circuit degrade (e.g., loosen, etc.) during the operation of the component stack 1700, the performance of the IC package 1708 can worsen or become inoperable. In other examples, the socket 1706 can be implemented by any other suitable type of socket (e.g., a ball grid array, a pin grid array, etc.). In FIG. 17, the socket 1706 is coupled to the PCB 1712 via the bolster plate 1710. The bolster plate 1710 aligns and retains the socket 1706 on the PCB 1712. While examples described herein are described with reference to pins of the socket (e.g., the socket 1706, etc.) being received by features of the IC package (e.g., the IC package 1708, etc.), the teachings of this disclosure can also be applied to the opposite arrangement (e.g., pins of the IC package 1708 being received by corresponding features of the socket 1706, etc.). In some examples, the socket 1706 can implement a means for receiving the IC package 1708.

The component stack 1700 structurally supports the IC package 1708 by retaining the IC package 1708 within the socket 1706 via the compressive force of the fasteners 1716A, 1716B, 1716C, 1716D. The component stack 1700 communicatively couples the IC package 1708 via the socket 1706. The component stack 1700 also thermally regulates the operation of the IC package 1708 via heat transfer from the IC package 1708 to the heatsink 1702. The heatsink 1702 then discharges heat into the environment (e.g., via radiation, via convection, etc.). The component stack 1700 is suitable for use in air-cooled systems, immersion-cooled systems, and/or hybrid systems.

The back plate 1714 is a structural component coupled below the PCB 1712. The back plate 1714 is a stiff plate that prevents damage to the PCB 1712 due to the load caused by the coupling of the fasteners 1716A, 1716B, 1716C, 1716D to the bolster plate 1710. In some examples, the back plate 1714 also removes heat from the integrated PCB 1712 via conduction. In FIG. 17, the back plate 1714 is coupled (e.g., via features on the back plate 1714, etc.) to the bolster plate 1710. In FIG. 17, the back plate 1714 includes a cavity 1718 to enable one or more components (e.g., capacitors) on a back side of the PCB 172 to extend therethrough.

The fasteners 1716A, 1716B, 1716C, 1716D are coupled to the respective features of the bolster plate 1710 and the heatsink 1702, thereby retaining the heatsink 1702, the carrier 1704, the socket 1706, the IC package 1708 and the back plate 1714 on the PCB 1712. In FIG. 17, the fasteners 1716A, 1716B, 1716C, 1716D are polyetheretherketone (PEEK) nuts including anti-tilt features. In other examples, the fasteners 1716A, 1716B, 1716C, 1716D can be implemented by any other suitable fasteners.

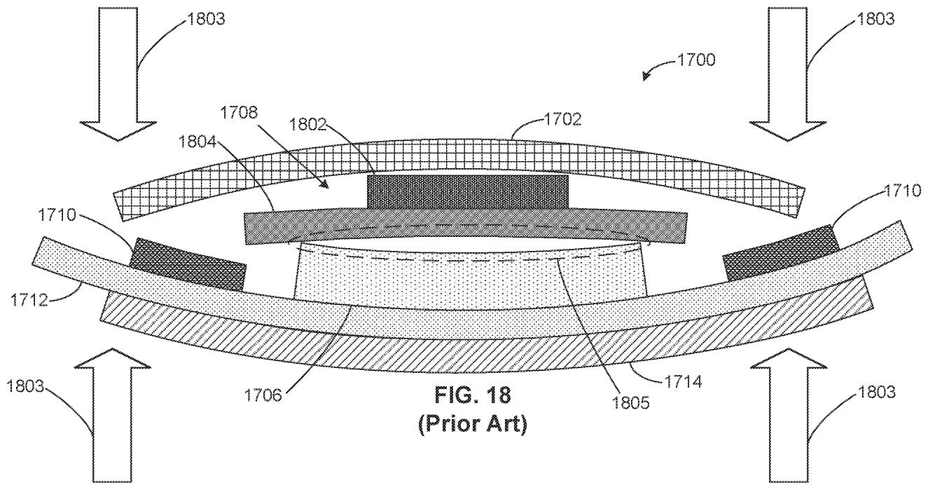

Because the fasteners 1716A, 1716B, 1716C, 1716D are proximate to the edges of the back plate 1714 and the bolster plate 1710, the tightening of the fasteners 1716A, 1716B, 1716C, 1716D can cause the back plate 1714 to warp concavely (e.g., relative to the PCB 1712, etc.). In some examples, the warping of the back plate 1714 can cause similar warpage of the PCB 1712 and the socket 1706, which can reduce the contact force between the socket 1706 and the IC package 1708 and/or cause a gap to form between the socket 1706 and the IC package 1708, thereby reducing the performance of the IC package 1708. A side view of the component stack 1700 undergoing such warpage is described below in additional detail in conjunction with FIG. 18.

FIG. 18 is a cross-sectional side view of the prior component stack 1700 of FIG. 17. In FIG. 18, the component stack 1700 includes the heatsink 1702 of FIG. 17, the socket 1706 of FIG. 17, the IC package 1708 of FIG. 17, the bolster plate 1710 of FIG. 17, the PCB 1712 of FIG. 17, and the back plate 1714 of FIG. 17. In FIG. 18, the IC package 1708 includes an IHS 1802 and an integrated circuit 1804. The IHS 1802 conducts heat from the IC package 1708 and into the heatsink 1702. For example, the IHS 1802 can be a planar member formed by a thermally conductive material (e.g., copper, aluminum, gold, silver, etc.). In other examples, the IHS 1802 can have any suitable shape and/or be composed of any suitable material. In some examples, a thermal interface material (TIM) is disposed between the IHS 1802 and the heatsink 1702 to facilitate heat transfer therebetween.

In FIG. 18, the tightening of the fasteners 1716A, 1716B, 1716C, 1716D (not visible in FIG. 18) causes a compressive force 1803 to be applied to the edges of the component stack 1700. The compressive force 1803 retains the components of the component stack 1700. In FIG. 18, because the compressive force 1803 is applied on the edges of the component stack 1700, a gap 1805 is formed between the integrated circuit 1804 and the socket 1706. That is, in FIG. 18, the tightening of the fasteners 1716A, 1716B, 1716C, 1716D and the resulting compressive force 1803 causes the edges of the components of the component stack 1700 (e.g., the heatsink 1702, the IHS 1802, the integrated circuit 1804, the socket 1706, the PCB 1712, and the back plate 1714, etc.) to bend towards the centerline of the component stack 1700. In FIG. 18, the internal faces of the heatsink 1702, the IHS 1802, the integrated circuit 1804 have a downward concave profile and the internal faces of the back plate 1714, the PCB 1712, the socket 1706, and the bolster plate 1710 have an upward concave profile. In FIG. 18, after assembly (e.g., the tightening of the 1716A, 1716B, 1716C, 1716D and the resulting compressive force 1803, etc.), the component stack 1700 can assume a generally convex external profile. Notably, the bending or warpage of the components illustrated in FIG. 18 is exaggerated for purposes of explanation.

The gap 1805 reduces the contact area between the socket 1706 and the IC package 1708, thereby reducing the efficacy of the IC package 1708. The gap 1805 of FIG. 18 is not to scale and may be exaggerated in size for illustrative and demonstrative purposes only. Gaps in contact between socket 1706 and the IC package 1708 that are comparatively smaller than the gap 1805 can also cause significant reductions in the performance of the IC package 1708 and the component stack 1700.

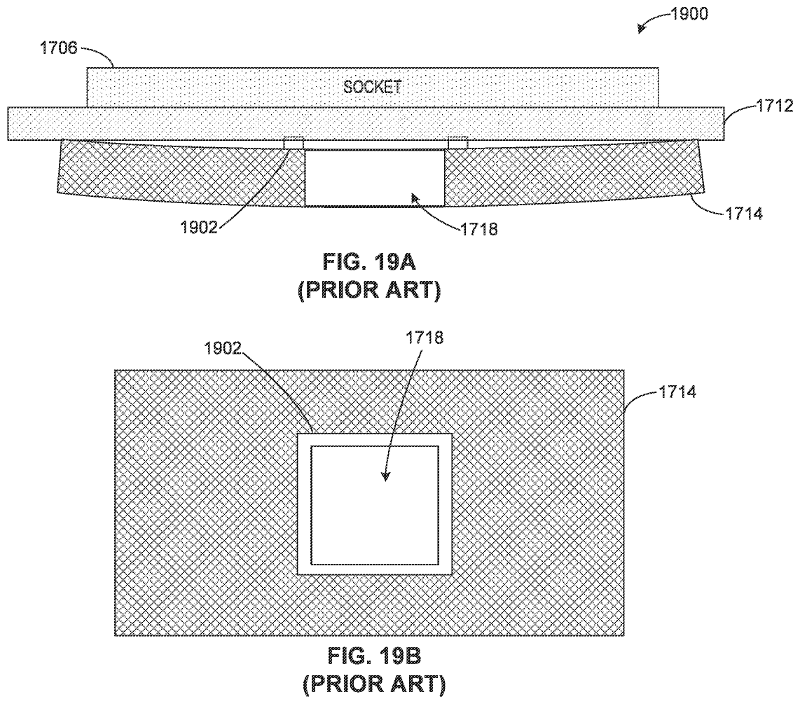

FIG. 19A is a cross-sectional side view of a prior back plate assembly 1900 that partly obviates the deficiencies of the component stack 1700 caused by the formation of the gap 1805. The back plate assembly 1900 includes the socket 1706 of FIG. 17, the PCB 1712 of FIG. 17, the back plate 1714, and a shim 1902. FIG. 19B is a top view of the back plate 1714 and the shim 1902. In FIGS. 19A and 19B, the shim 1902 is disposed about the cavity 1718 of the back plate 1714. In FIGS. 19A and 19B, contact forces of the shim 1902 prevent some of the warpage of the socket 1706 and the PCB 1712, thereby increasing the pin contact in areas of the socket 1706 directly above the shim 1902. However, the socket pins distal from the shim 1902 still have reduced contact. The shim 1902 can be composed of a polymer and/or any other suitable material.

The following examples refer to component stacks, back plates, and/or back plate assemblies, similar to the component stacks, back plates, and/or back plate assemblies described with reference to FIGS. 17-19B, except that the back plates assemblies include features that serve to improve pin contact between the IC package 1708 and the socket 1706, in accordance with this disclosure. When the same element number is used in connection with FIGS. 20-41 as was used in FIGS. 17-19B, it has the same meaning unless indicated otherwise.

FIG. 20 is a cross-sectional side view of an example back plate assembly 2000 including an example back plate 2001 and an example spring sheet 2002 implemented in accordance with teachings of this disclosure. In the illustrated example of FIG. 20, the spring sheet 2002 has been joined to the back plate 2001. The spring sheet 2002 has an example first end 2004A and an example second end 2004B.

The spring sheet 2002 is a thin sheet that has been pre-shaped and coupled to an example top surface 2006 of the back plate 2001. In the illustrated example of FIG. 20, the spring sheet 2002 has been shaped (e.g., during manufacturing, etc.) to have an example profile 2008 (e.g., a curvature, a curvature profile, a non-planar profile, etc.). In other examples, the spring sheet 2002 can be elastically deformed into the profile 2008 during the coupling of the spring sheet 2002 to the back plate 2001. In the illustrated example of FIG. 20, the profile 2008 is curved (e.g., an arc, a parabolic curve, a sinusoidal curve, etc.). In the illustrated example of FIG. 20, the profile 2008 defines a concave curvature oriented towards the back plate 2000 and a convex curvature oriented opposite the back plate 2000. In other examples, the profile 2008 can have any other suitable shape(s) (e.g., multiple curves, a V-shape, multiple V-shapes, U-shaped, etc.). In the illustrated example of FIG. 20, the spring sheet 2002 is joined to back plate at the ends 2004A, 2004B. The example spring sheet 2002 can be coupled at the ends 2004A, 2004B to the back plate 2001 via one or more welds, one or more fasteners, one or more chemical adhesives, a press fit into a corresponding feature of the back plate 2001, a shrink fit into a corresponding feature of the back plate 2001, and/or a combination thereof. Additionally or alternatively, the spring sheet 2002 can be coupled to the back plate 2001 via compression (e.g., the compression force 1803, etc.) and/or frictional forces. In some examples, the spring sheet 2002 is only coupled to the back plate 2001 at one of the ends 2004A, 2004B while the other end is free to move relative to back plate. In some examples, the spring sheet 2002 includes openings that align with cavities in the back plate 2001 (e.g., similar to the cavity 1718 in the back plate 1714 of FIG. 17). Additionally or alternatively, in some examples the spring sheet 2002 includes holes to permit studs (such as those shown protruding from the back plate 1714 in FIG. 17) to extend therethrough to enable the back plate 1714 to be connected with the bolster plate 1710 on the other side of the PCB 1712.

The profile 2008 of the spring sheet 2002 causes the spring sheet 2002 to resist compressive forces applied to the top of the spring sheet 2002 by applying a counteracting spring force. In some examples, when the top of the spring sheet 2002 is loaded, the spring sheet 2002 applies a tensional force to the back plate 2001, which can mitigate the warpage of the back plate 2001 associated with the tightening of fasteners (e.g., the fasteners 1716A, 1716B, 1716C, 1716D of FIG. 17, etc.). Examples of the back plate assembly 2000 both before tightening and after tightening of the fasteners are described below in FIGS. 21 and 22, respectively.

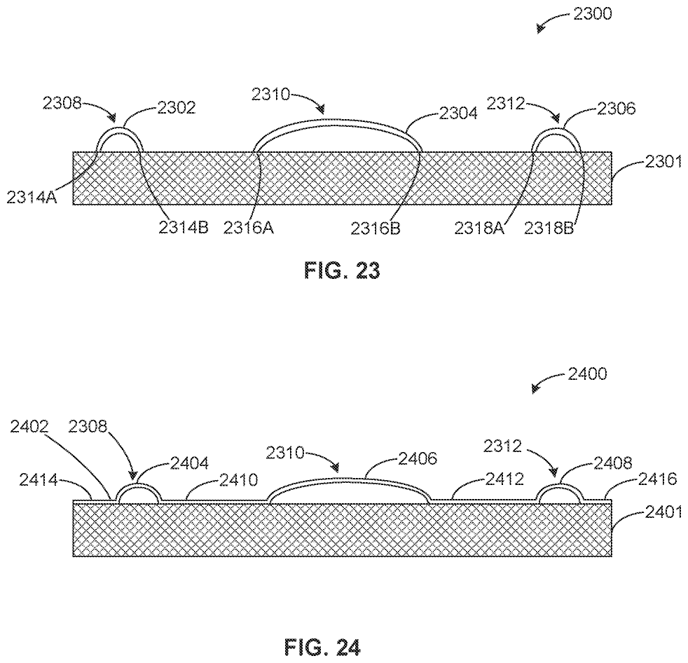

In some examples, the spring sheet 2002 can be manufactured from any suitable non-brittle high-yield strength material (e.g., can undergo repeated elastic deformation, etc.). For example, the spring sheet 2002 can be composed of carbon steel (e.g., spring steel, etc.), alloy steel, nickel alloys, copper, stainless steel, titanium, and/or a combination thereof. In other examples, the spring sheet 2002 can be composed of any other material. In the illustrated example of FIG. 20, the profile 2008 of the spring sheet 2002 extends a substantial portion of the entire length of the back plate 2001. In other examples, the spring sheet 2002 can be disposed adjacent to the center of the back plate 2001. In other examples, the spring sheet 2002 can include a portion in the center of the back plate 2001 and/or other portions near the edge of the back plate 2001. Other example spring sheets implemented in accordance with teachings of this disclosure are described below in conjunction with FIGS. 23-25.

FIG. 21 is a cross-sectional side view of the example back plate assembly 2000 of FIG. 20 in an example pre-tightened state 2102. In the illustrated example of FIG. 21, the back plate assembly 2000 includes the example socket 1706 of FIG. 17, the PCB 1712 of FIG. 17, the spring sheet 2002 of FIG. 20, and the back plate 2001 of FIG. 20. In the pre-tightened state 2102 of FIG. 21, the back plate assembly 2000 has not been tightened (e.g., the fasteners 1716A, 1716B, 1716C, 1716D of FIG. 17 have not been tightened to apply a load to the component stack, etc.) and the spring sheet 2002 has not been elastically deformed.

FIG. 22 is a cross-sectional side view of the back plate assembly 2000 of FIGS. 20-21 in a tightened state 2200. For example, fasteners (e.g., the fasteners 1716A, 1716B, 1716C, 1716D of FIG. 17, etc.) can be coupled to a heatsink (e.g., the heatsink 1702 of FIG. 17) disposed above the socket 1706 and the back plate 2001, thereby moving the back plate assembly 2000 from the pre-tightened state 2102 of FIG. 21 to the tightened state 2200. In the illustrated example of FIG. 22, the tightened state 2200 causes the example compressive force 1803 to be applied to the back plate assembly 2000. In the illustrated example of FIG. 22, the tightened state 2200 causes the spring sheet 2002 to flatten, which causes the spring sheet to apply an example force 2202 (at the ends 2004A, 2004B) on the back plate 2000 that counteracts the compressive force 1803 causing the bending or warpage in the back plate 2000. Further, as the spring sheet 2002 is flattened between the back plate 2000 and the PCB 1712, the spring sheet produces a force 2203 (at a central portion of the spring sheet 2002) on the PCB 1712 that counteracts the forces causing the bending or warpage of the PCB 1712 and the socket 1706 attached thereto.

In the illustrated example of FIG. 22, the spring sheet 2002 has been flattened (e.g., made planar, etc.) by the compressive force 1803. The flattening of the spring sheet 2002 applies an example spring force 2203 in opposition to the compressive force 1803. In the illustrated example of FIG. 22, the force 2202 counteracts (e.g., partly counteracts, fully counteracts, etc.) the warpage caused by compressive force 1803, thereby maintaining the flat (e.g., planar, etc.) shape of the back plate 2001. In the illustrated example of FIG. 22, because the warpage of the back plate 2001 is reduced (e.g., minimized, prevented, etc.), gap formation between the socket 1706 and the coupled integrated circuit (not illustrated) is also reduced (e.g., minimized, prevented, etc.). Additionally, the spring force 2203 applied at the center of the socket 1706 improves contact between the socket 1706 and the IC package (not illustrated). As such, the spring sheet 2002 improves contact between the pins of the socket 1706 and the coupled integrated circuit and the performance of the associated component stack.

FIG. 23 is a side view of another back plate assembly 2300 including an example back plate 2301, an example first spring sheet 2302, an example second spring sheet 2304, and an example third spring sheet 2306. In the illustrated example of FIG. 23, the first spring sheet 2302 has an example first profile 2308, the second spring sheet 2304 has an example second profile 2310, and the third spring sheet 2306 has an example third profile 2312. In the illustrated example of FIG. 23, the first spring sheet 2302 has an example first end 2314A and an example second end 2314B, the second spring sheet 2304 has an example third end 2316A and an example fourth end 2316B, and the third spring sheet 2306 has an example fifth end 2318A and an example sixth end 2318B.

The second spring sheet 2304 is disposed between the first spring sheet 2302 and the third spring sheet 2306. In the illustrated example of FIG. 23, the second spring sheet 2304 is generally aligned with the center of the back plate 2301, such that the second spring sheet 2304 is generally aligned with the center of a socket (e.g., the socket 1706 of FIG. 17, etc.) and/or the integrated circuit (e.g., the IC package 1708, etc.) when the back plate 2301 is coupled to a heatsink (e.g., the heatsink 1702, etc.). The second spring sheet 2304 functions similarly to the spring sheet 2002 of FIGS. 20-22 by mitigating back plate bending during assembling, thereby maintaining pin contact during operation. In the illustrated example of FIG. 23, the second spring sheet 2304 is joined to the back plate 2301 at the ends 2314A, 2314B. The second spring sheet 2304 can be coupled at the ends 2314A, 2314B to the back plate 2301 via one or more welds, one or more fasteners, one or more chemical adhesives, a press fit into a corresponding feature of the back plate 2301, a shrink fit into a corresponding feature of the back plate 2301, and/or a combination thereof.

The first spring sheet 2302 and the third spring sheet 2306 are coupled proximate to the respective edges of the back plate 2301. In the illustrated example of FIG. 23, the first spring sheet 2302 and the third spring sheet 2306 are on opposite sides of the second spring sheet 2304. In the illustrated example of FIG. 23, the first spring sheet 2302 and the third spring sheet 2306 are closer to the edges of the back plate 2301 than to the second spring sheet 2304. In some examples, the operation of a component stack (e.g., the component stack 1700 of FIG. 17, etc.), a heatsink (e.g., the heatsink 1702 of FIG. 17, etc.) and/or an integrated circuity (e.g., the IC package 1708, etc.) can generate vibrations and/or small oscillatory movements. In some examples, the generated vibrations cause the largest oscillatory movements near the edges of the back plate 2301. In some such examples, the generated vibration can cause fretting (e.g., the formation of asperities, the formation of pits, surface damage, etc.) on the edges of the back plate 2301 and/or the associated areas of the coupled PCB (e.g., the coupled PCB 1712, etc.). In some examples, the first spring sheet 2302 and the third spring sheet 2306 can dampen the resulting vibration, thereby reducing the associated fretting and increasing the component life of the back plate 2301 and coupled PCB. The first spring sheet 2302 and the third spring sheet 2306 are coupled at the ends 2312A, 2314B and the ends 2318A, 2318B, respectively, to the back plate 2301 via one or more welds, one or more fasteners, one or more chemical adhesives, a press fit into a corresponding feature of the back plate 2301, a shrink fit into a corresponding feature of the back plate 2301, and/or a combination thereof.

The spring sheets 2302, 2304, 2306 can be manufactured from any suitable non-brittle high-yield strength material(s) (e.g., can undergo elastic deformation, etc.). For example, the spring sheets 2302, 2304, 2306 can be composed of carbon steel (e.g., spring steel, etc.), alloy steel, nickel alloys, copper, stainless steel, titanium, and/or a combination thereof. In other examples, the spring sheets 2302, 2304, 2306 can be composed of any other material(s). In some examples, the spring sheets 2302, 2304, 2306 can be composed of a same material. In other examples, different ones of the spring sheets 2302, 2304, 2306 can be composed of different materials.

In the illustrated example of FIG. 23, the first profile 2308 of the first spring sheet 2302 and the third profile 2312 of the third spring sheet 2306 are the same. In other examples, the first profile 2308 and the third profile 2312 can be different profiles (e.g., different curves, etc.). In the illustrated example of FIG. 23, the spring sheets 2302, 2304, 2306 have the same thickness (e.g., manufactured from a stock of the same thickness, etc.). In other examples, some or all of the spring sheets 2302, 2304, 2306 can have different thicknesses. Additionally or alternatively, other shapes at any of the spring locations 2302, 2304, 2306 are also possible. For example, instead of curved surfaces, a flat portion of the spring sheet(s) 2302, 2304, 2306 can be bent at an angle relative to the back plate 2301 to define a tab or flap that extends away from the surface of the back plate 2301.

FIG. 24 is a side view of another back plate assembly 2400 including an example back plate 2401 and an example spring sheet 2402. In the illustrated example of FIG. 24, the spring sheet 2402 includes an example first spring location 2404, an example second spring location 2406, an example third spring location 2408, an example first intermediate portion 2410, an example second intermediate portion 2412, an example first end portion 2414 and an example second end portion 2416. In the illustrated example of FIG. 24, the first spring location 2404 has the example first profile 2308 of FIG. 23, the second spring location 2406 has the example second profile 2310 of FIG. 23, and the third spring location 2410 has the example third profile 2312 of FIG. 23.

In the illustrated example of FIG. 24, the spring sheet 2402 is a single integral part that includes multiple distinct spring locations, namely the spring locations 2404, 2406, 2408. As used herein, the term “spring location” refers to a portion of a spring sheet that acts as an independent spring when a compressive force is applied. In the illustrated example of FIG. 24, the spring sheet 2402 can be pre-shaped during manufacturing to include curves associated with the spring locations 2404, 2406, 2408. Additionally or alternatively, other shapes at any of the spring locations 2404, 2406, 2408 are also possible. For example, instead of curved surfaces, a flat portion of the spring sheet 2402 can be bent at an angle relative to the intermediate and/or end portions 2410, 2412, 2414, 2416 to define a tab or flap that extends away from the surface of the back plate 2401. While the spring sheet 2402 includes the three spring locations 2404, 2406, 2408, in other examples, the spring sheet 2402 can include any suitable number of spring locations (e.g., two spring locations, four spring locations, etc.). In the illustrated example of FIG. 24, the spring locations 2404, 2406, 2408, the intermediate portions 2410, 2412, and the end portions 2414, 2416 have a same thickness. In other examples, some or all of the spring locations 2404, 2406, 2408, the intermediate portions 2410, 2412, and/or the end portions 2414, 2416 can have different thicknesses.

The spring sheet 2402 can be joined to the back plate 2401 at the intermediate portions 2410, 2412 and/or the end portions 2414, 2416 via one or more welds, one or more fasteners, one or more press fits with a corresponding feature of the back plate 2401, one or more shrink fits of the back plate 2401, a chemical adhesive, etc.

The second spring location 2406 is disposed between the first spring location 2404 and the third spring location 2408. In the illustrated example of FIG. 24, the second spring location 2406 is generally aligned with the center of the back plate 2400, such that the second spring location 2406 is generally aligned with the center of a socket (e.g., the socket 1706 of FIG. 17, etc.) and/or the integrated circuit (e.g., the IC package 1708, etc.) when the back plate 2400 is coupled to a heatsink (e.g., the heatsink 1702, etc.). The first spring location 2404 and the third spring location 2408 are disposed at the respective edges of the back plate 2400 and near the end of the spring sheet 2402. In the illustrated example of FIG. 24, the first spring location 2404 and the third spring location 2408 are on opposite sides of the second spring location 2406. In the illustrated example of FIG. 24, the first spring location 2404 and the third spring location 2408 are closer to the edges of the back plate 2400 than to the second spring location 2406.

In the illustrated example of FIG. 24, the spring sheet 2402 has similar functionality as the spring sheets 2302, 2304, 2306 of FIG. 23. In some examples, the second spring location 2406 mitigates the bending of the back plate 2401 during assembly and operation, thereby maintaining pin contact during operation, similarly to the second spring sheet 2304. In some examples, the first spring location 2404 and the third spring location 2408 mitigate vibration fretting, similarly to the first spring sheet 2302 and the third spring sheet 2306. While the spring sheet 2402 offers similar functionality as the spring sheets 2302, 2304, 2306, the spring sheet 2402 can have comparatively reduced cost and manufacturing complexity due to the spring sheet 2402 being a single integral component.

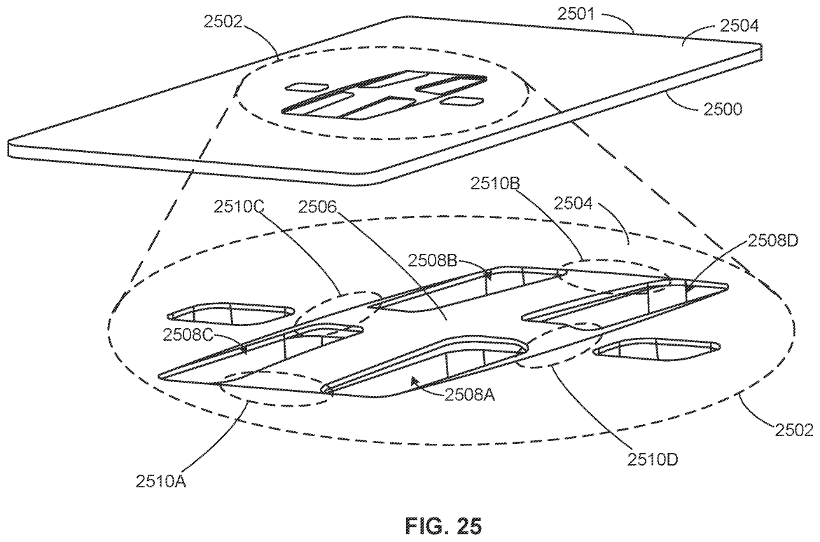

FIG. 25 is a perspective view of another example back plate 2500 and example spring sheet 2501 implemented in accordance with teachings of this disclosure. In the illustrated example of FIG. 25, the back plate 2500 has an example center region 2502. In the illustrated example of FIG. 25, the spring sheet 2501 has an example spring location 2506 aligned with the center region 2502. The spring sheet 2501 has an example planar portion 2504 that defines a plane that is parallel to the back plate 2500. In the illustrated example of FIG. 25, the back plate 2500 has an example first cavity 2508A, an example second cavity 2508B, an example third cavity 2508C, and an example fourth cavity 2508D. In the illustrated example of FIG. 25, the cavities 2508A, 2508B, 2508C, 2508D are generally arranged in a 2×2 grid in the center region 2502. In other examples, the cavities 2508A, 2508B, 2508C, 2508D can have any other suitable arrangement. In other examples, the back plate 2500 can include any suitable number of cavities.

In the illustrated example of FIG. 25, the spring location 2506 is disposed on the portion of the back plate 2500 that is to be coupled beneath the area of the socket (e.g., the socket 1706, etc.) with reduced pin contact force (e.g., the area associated with the gap 1805 of FIG. 18, etc.). In other examples, the spring location 2506 can be disposed at any other suitable location (e.g., around the edges of the back plate 2500, etc.). In other examples, the spring sheet 2501 can have any suitable number of other spring locations. In some examples, the back plate 2500 can include additional spring sheets.

In the illustrated example of FIG. 25, the spring sheet 2501 is a thin sheet disposed on the back plate 2500. In the illustrated example of FIG. 25, the spring location 2506 is generally cross-shaped (e.g., plus-shaped, X-shaped, etc.). In the illustrated example of FIG. 25, interfaces 2510A, 2510B, 2510C, 2510D are located at the respective ends of the spring location 2506 and form the interface between the planar portion 2504 of the spring sheet and the spring location 2506. In the illustrated example of FIG. 25, the first interface 2510A is disposed between the first cavity 2508A and the third cavity 2508C. In other examples, the first interface 2510A can be disposed at any other suitable location (e.g., a corner of the first cavity 2508A, a corner of the third cavity 2508C, etc.). In the illustrated example of FIG. 25, the second interface 2510B is disposed between the second cavity 2508B and the fourth cavity 2508D. In other examples, the second interface 2510B can be disposed at any other suitable location (e.g., a corner of the second cavity 2508B, a corner of the fourth cavity 2508D, etc.). In the illustrated example of FIG. 25, the third interface 2510C is disposed between the second cavity 2508B and the third cavity 2508C. In other examples, the third interface 2510C can be disposed at any other suitable location (e.g., a corner of the second cavity 2508B, a corner of the third cavity 2508C, etc.). In the illustrated example of FIG. 25, the fourth interface 2510D is disposed between the first cavity 2508A and the fourth cavity 2508D. In other examples, the fourth interface 2510D can be disposed at any other suitable location (e.g., a corner of the first cavity 2508A, a corner of the fourth cavity 2508D, etc.). Additionally or alternatively, the spring location 2506 can have any other suitable shape and/or orientation.

The spring sheet 2501 can be composed of any suitable non-brittle high-yield strength material. For example, the spring sheet 2501 can be composed of carbon steel (e.g., spring steel, etc.), alloy steel, nickel alloys, copper, stainless steel, titanium, and/or a combination thereof. In other examples, the spring sheet 2501 can be composed of any other material. In some examples, the back plate 2500 can be composed of any suitable material (e.g., steel, nickel-alloy, iron, copper, aluminum, etc.). In some examples, the spring sheet 2501 and the back plate 2500 are composed of a same material or a similar material (e.g., different types of steel, etc.). In other examples, the spring sheet 2501 and the back plate 2500 are composed of different materials.

In some examples, the spring sheet 2501 and the back plate 2500 are integral components. In some such examples, the spring sheet 2501 and/or the spring location 2506 can be formed in/on the back plate 2500 via stamping and/or any other suitable manufacturing process. In other examples, the spring sheet 2501 can be manufactured separately (e.g., via stamping, via machining, via additive manufacturing, via casting, etc.) and coupled to the back plate 2500 (e.g., via one or more welds, one or more fasteners, one or more chemical adhesives, via a press fit into a corresponding feature of the back plate 2500, via a shrink fit into a corresponding feature of the back plate 2500, etc.). In other examples, the spring sheet 2501 and/or the spring location 2506 can be formed and/or coupled to the back plate 2500 in any other suitable manner. In some examples, a spring sheet (e.g., the spring sheet 2501 of FIG. 25, spring sheet 2402 of FIG. 24, the spring sheets 2302, 2304, 2306 of FIG. 32, spring sheet 2002, etc.) can implement a means for increasing pin contact between a socket and a coupled integrated circuit.

FIGS. 26-29 are side views of an example pre-shaped back plate 2600 implemented in accordance with teachings of this disclosure. FIG. 26 is a cross-sectional view of the pre-shaped back plate 2600 in an example first state 2602. In the illustrated example of FIG. 26, the pre-shaped back plate 2600 includes an example first layer 2604 and an example second layer 2606. While the pre-shaped back plate 2600 described in conjunction with FIGS. 26-29 is composed of two layers (e.g., the layers 2604, 2606, etc.). In other examples, the pre-shaped back plate 2600 can be composed of any other suitable number of layers (e.g., one layer, three layers, four layers, etc.).

The first layer 2604 and the second layer 2606 are flat structural components (e.g., planar structural members, sheets, etc.) that compose the pre-shaped back plate 2600. In some examples, one or both of the first layer 2604 and the second layer 2606 can include voids and/or cavities. In the illustrated example of FIG. 26, the first layer 2604 is joined to the second layer 2606. For example, the first layer 2604 and the second layer 2606 can be joined via one or more welds, one or more chemical adhesives, one or more fasteners, etc.) In some examples, the first layer 2604 and the second layer 2606 can be integral (e.g., formed via additive manufacturing, etc.). In the illustrated example of FIG. 26, the first layer 2600 has different thermal properties than the second layer 2606. The example first state 2602 corresponds to the back plate 2600 at an elevated temperature (e.g., a temperature beyond which the back plate 2600 is expected to experience when in use). In the illustrated example of FIG. 26, the different thermal properties of the layers 2604, 2606 cause the layers 2604, 2606 to be approximately the same length at the elevated temperature associated with the first state 2602. As such, when the materials are joined the pre-shaped back plate 2600 is substantially planar (e.g., flat, etc.).

In some examples, the layers 2604, 2606 can have equal thickness (e.g., substantially equal thicknesses, etc.). In other examples, the layers 2604, 2606 can have different thicknesses. In some examples, the combined thicknesses of the layers 2604, 2606 can equal to the total thickness of the back plate 2600. In some examples, the layers 2604, 2606 define top and bottom surfaces with substantially equal surface areas. In some examples, the top faces of the layers 2604, 2606 and the bottom faces of the layers 2604, 2606 have a surface area that is substantially equal to the surface equal of the back plate 2600. In other examples, the faces of the layers 2604, 2606 and/or the faces of the bottom plate 2600 can have a different relationship.

The first layer 2604 can be composed of a different material than the second layer 2606. For example, the first layer 2604 can be composed of a first metal (e.g., steel, cast iron, copper, aluminum, a nickel alloy, etc.) and/or a first composite material (e.g., carbon fiber, fiberglass, an aromatic polyamide, a ceramic matrix composite, a metal matrix composite, etc.) and the second layer 2606 can be composed of a second metal different than the first metal and/or a second composite material different than the first composite material. In some such examples, the different materials of the layers 2604, 2606 can have a different coefficient of thermal expansion (CTE). As used herein, CTE refers to a rate at which a material expands when heated. CTE can be expressed as a ratio of a change in a dimensional value (e.g., volume, area, or length, etc.) to a corresponding change in temperature (e.g., a CTE of 0.01 implies that a that material expands 1% in length per degree of temperature increase, etc.). In some such examples, the greater the CTE, the greater a material will expand when heated and/or contract when cooled.

The first layer 2604 can have a higher CTE than the second layer 2606. In other examples, the first layer 2604 and the second layer 2606 can be composed of a same material. In such examples, the different thermal properties of the layers 2604, 2606 can be associated with a different geometry of the layers 2604, 2606. For example, one or both of the layers 2604, 2606 can have voids and/or cavities. Additionally or alternatively, one of both of the layers 2604, 2606 can have an internal lattice structure. In some examples, one or both the layers 2604, 2606 can be composed of a smart metal alloy (SMA). In some examples, the layers 2604, 2606 can have different stiffness(es). In other examples, the layers 2604, 2606 can have a same stiffness.

FIG. 27 is a cross-sectional view of the pre-shaped back plate 2600 in an example second state 2700. In the illustrated example of FIG. 27, the second state 2700 is at a comparatively lower temperature (e.g., room temperature, an average temperature at which the back plate 2600 is expected to be used, etc.) than the first state 2602 of FIG. 26. Because the first layer 2604 has a different thermal property (e.g., a higher CTE, etc.) than the second layer 2606 and the layers 2604, 2606 have been fixedly joined (e.g., the ends 2704A, 2704B are fixedly joined, a portion of the layers have been fixedly joined, etc.), the first layer 2604 thermally contracts less than the second layer 2606, thereby causing the pre-shaped back plate 2600 to assume an example profile 2702. In the illustrated example of FIG. 27, the profile 2702 is a curved profile. The profile 2702 causes an example top surface 2706 of the pre-shaped back plate 2600 (e.g., the top surface of the first layer 2604, etc.) to have a convex orientation and an example bottom surface 2708 of the back plate (e.g., the bottom surface of the second layer 2606, etc.) to have a concave orientation, etc. Accordingly, the different thermal properties of the layers 2604, 2606 cause the pre-shaped back plate 2600 to have a pre-shaped profile 2702 at the second state 2700 (e.g., at room temperature, etc.).

FIG. 28 is a cross-sectional side view of an example back plate assembly 2800 in an example pre-tightened state 2801. In the illustrated example of FIG. 21, the back plate assembly 2800 includes the example socket 1706 of FIG. 17, the PCB 1712 of FIG. 17, and the pre-shaped back plate 2600 of FIGS. 26 and 27. In the pre-tightened state 2801, the back plate assembly 2000 has not been tightened (e.g., the fasteners 1716A, 1716B, 1716C, 1716D of FIG. 17 have not applied a compressive load to the component stack, etc.) and the pre-shaped back plate 2600.

FIG. 29 is a cross-sectional side view of the back plate assembly 2800 in an example tightened state 2900. For example, fasteners (e.g., the fasteners 1716A, 1716B, 1716C, 1716D of FIG. 17, etc.) can be coupled to a heatsink (e.g., the heatsink 1702 of FIG. 17) disposed above the socket 1706 and the pre-shaped back plate 2600, thereby moving the back plate assembly 2000 from the pre-tightened state 2801 of FIG. 28 to the tightened state 2900.

In the illustrated example of FIG. 29, the tightened state 2900 causes the example compressive force 1803 of FIG. 18 to be applied to the pre-shaped back plate 2600, the socket 1706, and the PCB 1712. In the illustrated example of FIG. 29, the tightened state 2900 causes the pre-shaped back plate 2600 to elastically deform to a planar (e.g., flattened, etc.) condition. In the illustrated example of FIG. 29, the flattening of the pre-shaped back plate 2600 compensates for the warpage associated with the compressive force 1803. More particularly, the convex surface pressed against the PCB 1712 in the tightened state 2900 causes a force on the PCB 1712 that counteracts the warpage that would otherwise occur if the back plate 2600 were flat (as represented in FIG. 18). In the illustrated example of FIG. 29, because the warpage of the pre-shaped back plate 2600 is compensated for a gap does not form (or is smaller than it otherwise would be) between the socket 1706 and the coupled integrated circuit (not illustrated). As such, the pre-shaped back plate 2600 improves contact between the pins of the socket 1706 and the coupled integrated circuit and the performance of the associated component stack. In some examples, a top surface of the back plate 2600 can implement a means for increasing pin contact between a socket and a coupled integrated circuit.

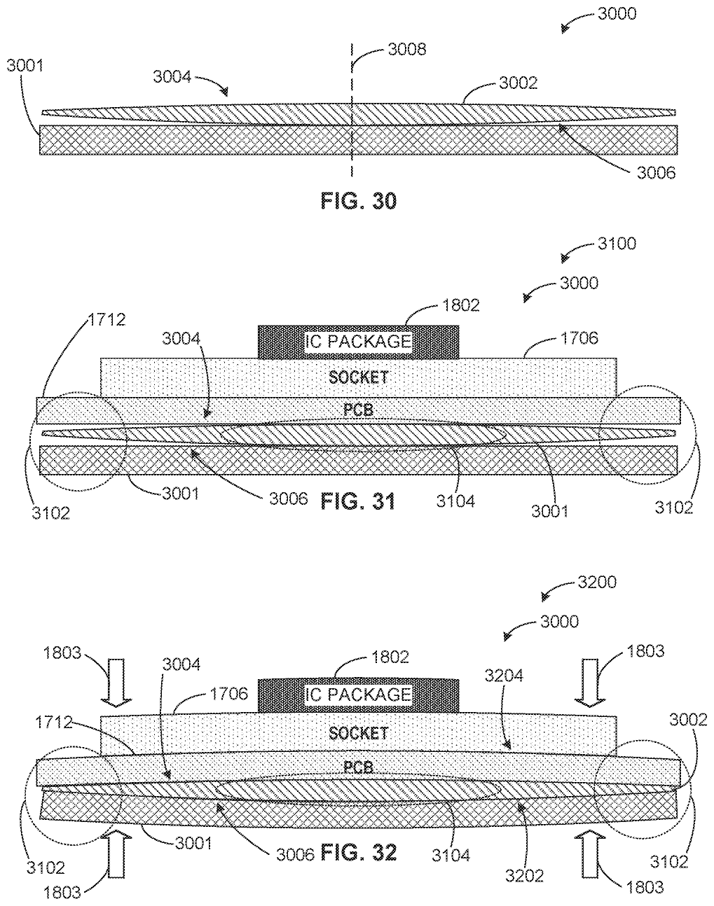

FIG. 30 is a cross-sectional side view of an example back plate assembly 3000 including an example back plate 3001 and an example spacer 3002 implemented in accordance with teachings of this disclosure. In the illustrated example of FIG. 30, the spacer 3002 has an example first profile 3004 and an example second profile 3006.

The spacer 3002 is a physical structure disposed on the back plate 3001. The spacer 3002 can be composed of an insulative material (e.g., glass, quartz, alumina, rubber, an insulative polymer, silicon, etc.). In other examples, the spacer 3002 can be composed of any suitable material. In the illustrated example of FIG. 30, the thickness of the spacer 3002 varies along the length of the back plate 3001 (e.g., the spacer 3002 is thicker near the center of the back plate 3001 and thinner near the edges of the back plate 3001, etc.). In the illustrated example of FIG. 31, the spacer 3002 is symmetrical about an example centerline 3008 of the back plate 3001. In other examples, the spacer 3002 is asymmetrical about an example centerline 3008 of the back plate 3001. In some examples, the thickness of the spacer 3002 can vary along the depth of the back plate 3001. In other examples, the thickness and/or shape of the spacer 3002 can have any suitable shape and/or thickness. In the illustrated example of FIGS. 30-32, the spacer 3002 directly abuts the back plate 3001. In some examples, one or more intermediate parts (e.g., an insulator, etc.) disposed between the spacer 3702 and the back plate 3306.

In the illustrated example of FIGS. 30-32, the spacer 3002 has the first profile 3004 (e.g., the top profile, etc.) and the second profile 3006. In the illustrated example of FIGS. 30-32, the profiles 3004, 3006 have a same curvature (e.g., a same arc, a same polynomial curve, etc.). In other examples, the profiles 3004, 3006 can have different curvatures. In the illustrated example of FIGS. 30-33, the profiles 3004, 3006 are convex profiles. In other examples, the profiles 3004, 3006 of the spacer 3002 can have any other suitable curvature(s) and/or shape(s).

FIG. 31 is a cross-sectional side view of an example back plate assembly 3000 of FIG. 30 in an example pre-tightened state 3100. In the illustrated example of FIG. 31, the back plate assembly 3000 includes the example socket 1706 of FIG. 17, the PCB 1712 of FIG. 17, and the pre-shaped back plate 2600 of FIGS. 26 and 27. In the pre-tightened state 2801, the back plate assembly 3000 has not been tightened (e.g., the fasteners 1716A, 1716B, 1716C, 1716D of FIG. 17 have not applied a compressive load to the component stack, etc.). In the illustrated example of FIG. 31, the profiles 3004, 3006 of the spacer 3002 cause an example edge area 3102 of the spacer 3002 to not abut the back plate 3001 and the PCB 1712. In some examples, the edge area 3102 extends (e.g., circumferentially extends, etc.) about the center of the spacer 3002. In other examples, the edge area 3102 can have any suitable shape. In the illustrated example of FIG. 31, an example center region 3104 of the spacer 3002 abuts the PCB 1712. In some examples, one or more intermediate parts may be disposed between the PCB 1712 and the spacer 3002.

FIG. 32 is a cross-sectional side view of the back plate assembly 3000 in an example tightened state 3200. For example, fasteners (e.g., the fasteners 1716A, 1716B, 1716C, 1716D of FIG. 17, etc.) can be coupled to a heatsink (e.g., the heatsink 1702 of FIG. 17) disposed above the socket 1706 and the pre-shaped back plate 2600, thereby moving the back plate assembly 3000 from the pre-tightened state 3100 of FIG. 21 to the tightened state 3200.

In the illustrated example of FIG. 32, the tightened state 3200 causes the example compressive force 1803 of FIG. 18 to be applied to the pre-shaped back plate 2600, the socket 1706, the PCB 1712, and the spacer 3002. In the illustrated example of FIG. 32, the tightened state 3200 causes the back plate 3001 to assume an example third profile 3202 and the PCB 1712 to assume an example fourth profile 3204. In the illustrated example of FIG. 32, the third profile 3202 of the back plate 3001 is complimentary with the second profile 3006 of the spacer 3002 (e.g., the top surface of the back plate 3001 abuts the spacer 3002 along the length and the depth of the back plate 3001, etc.). In the illustrated example of FIG. 32, the fourth profile 3204 of the PCB 1712 is complimentary with the first profile 3004 of the spacer 3002 (e.g., the bottom surface of the PCB 1712 abuts the spacer 3002 along the length and the depth of the back plate 3001, etc.).

In the illustrated example of FIG. 32, because the spacer 3002 prevents the PCB 1712 from warping in a manner similar to the back plate 3001, a gap does not form (or is smaller than it otherwise would be) between the socket 1706 and the coupled integrated circuit 1708. Additionally, the spacer 3002 ensures the load distribution between the socket 1706 and the IC package 1708 is more even across the length and the depth of the socket 1706. As such, the spacer 3002 improves contact between the pins of the socket 1706 and the coupled integrated circuit 1708 and the performance of the associated component stack. In some examples, the spacer 3002 can implement a means for increasing pin contact between a socket and a coupled integrated circuit.

FIG. 33 is an illustration of a prior component stack 3300. The prior component stack 3300 is similar to the component stack 1700 of FIGS. 17 and 18. In FIG. 33, the prior component stack 3300 includes an IC package 3302, a PCB-socket assembly 3304, and a back plate 3306. In FIG. 33, the fastening of the fasteners (not illustrated) (e.g., the fasteners 1716A, 1716B, 1716C, 1716D, etc.) subjects the component stack 3300 to a load distribution 3308. In FIG. 33, the load distribution 3308 has caused the IC package 3302, the PCB-socket assembly 3304, and the back plate 3306 to warp, creating a gap 3310 to form between the IC package 3302 and the PCB-socket assembly 3304. The gap 3310 reduces pin contact between the PCB-socket assembly 3304 and the IC package 3302 and the load distribution 3308 reduces the contact force between the PCB-socket assembly 3304 and the IC package 3302. The gap 3310 and the load distribution 3308 reduce the effectiveness of the component stack 3300 by interfering with the communication between the IC package 3302 and the PCB-socket assembly 3304.

FIG. 34 is an illustration of the bending of the IC package 3302 of FIG. 33 caused by an example idealized load distribution 3400. In the illustrated example of FIG. 34, the integrated package 3302 assumes an example profile 3402 (U_{Package}) when subjected to the load distribution 3308. In the illustrated example of FIG. 34, the load distribution 3400 is substantially equal along the IC package 3302 and represents a target load distribution which pin contact is maintained in the center of the PCB-socket assembly 3304. In the illustrated example of FIG. 34, the IC package 3302 undergoes warpage due to the load distribution 3400. In some examples, the stiffest portion of the IC package 3302 is the IHS and the profile 3402 is based on the stiffness of the IHS. As used herein, the term “stiffness” refers to resistance of an object to deformation and/or warpage. Stiffness can be expressed as a ratio of a force to the deformation associated with the application of the force and can be quantified by the Young's modulus (e.g., the modulus of elasticity). In some such examples, a higher Young's modulus indicates that the material is more resistant to deformation. In other examples, the amount of warpage of the IC package 3302 and the associated resulting profile 3402 can be based on any other suitable physical characteristic of the IC package 3302. In some examples, the profile 3402 can be used to determine the shape of the examples back plate assemblies of FIGS. 36-38 described below.

FIG. 35 is an illustration of the expected bending of the PCB-socket assembly 3304 of FIG. 17 caused by example idealized load distribution 3400. In the illustrated example of FIG. 35, the PCB-socket assembly 3304 assumes an example profile 3500 (U_{PCB}) when subjected to the load distribution 3308. In the illustrated example of FIG. 35, the PCB-socket assembly 3304 undergoes warpage due to the load distribution 3308. In some examples, if the back plate 3306 is stiffer than the PCB-socket assembly 3304, the warpage of the PCB-socket assembly 3304 is based on the stiffness of the back plate 3306. In other examples, the amount of warpage of the PCB-socket assembly 3304 and the associated resulting profile 3500 can be based on any other suitable physical characteristic of the PCB-socket assembly 3304. In some examples, the profile 3500 can be used to determine the shape of the examples of FIGS. 36-38 described below.

FIG. 36 is an illustration of an example component stack 3600 implemented in accordance with teachings of this disclosure. The example component stack 3600 includes the IC package 3302 of FIG. 33, the PCB-socket assembly 3304 of FIG. 33, the back plate 3306 of FIG. 33, and example spring sheet 3606. In the illustrated example of FIG. 36, the component stack 3600 has an example load distribution 3604. The example spring sheet 3606 can be implemented by one or more spring sheets, such as the spring sheet 2002 of FIGS. 20-22, the spring sheets 2302, 2304, 2306 of FIG. 23, the spring sheet 2402 of FIG. 24, and/or the spring sheet 2501 of FIG. 25. In the illustrated example of FIG. 36, the spring sheet 3606 has been deformed due to the loading of the fasteners associated with the component stack 3600 (e.g., the fasteners 1716A, 1716B, 1716C, 1716D, etc.). In some examples, the distance between the back plate 3306 and the PCB-socket assembly 3304 under socket loading is equal to the difference between the profile 3402 of the IC package 3302 of FIG. 34 and the profile 3500 of the PCB-socket assembly 3304 of FIG. 35. In other examples, the spring sheet 3606 can have any other suitable shape. In the illustrated example of FIG. 36, the spring sheet 3606 causes the PCB-socket assembly 3304 to have a shape profile that is complimentary to the shape profile of the IC package 3302 (as represented in FIG. 36) such that the distance between any two corresponding connectors (e.g., pins and lands) is approximately the same. In other words, the spring sheet 3606 reduces and/or eliminates the gap 1805 between the socket 1706 and the IC package 1708 shown in FIG. 18. As a result, the internal load distribution 3604 (e.g., the socket loading, etc.) of the component stack 3600 is approximately equal across the interface between the socket and the IC package when assembled within the component stack, thereby improving the performance of the component stack 3600.

FIG. 37 is an illustration of an example component stack 3700 that includes the back plate 3306 of FIGS. 30 and 33 and an example spacer 3702 implemented in accordance with teachings of this disclosure. The example component stack 3700 additionally includes the IC package 3302 of FIG. 33, and the PCB-socket assembly 3304 of FIG. 33. The example spacer 3702 can be implemented by one or more spacers, such as the spacer 3002 of FIGS. 30-32. In the illustrated example of FIG. 37, the component stack 3700 has an example internal load distribution 3704.

In the illustrated example of FIG. 37, the spacer 3702 is a physical structure disposed between the back plate 3306 and the PCB-socket assembly 3304. In the illustrated example of FIG. 37, the spacer 3702 abuts the PCB-socket assembly 3304 and the back plate 3306. In other examples, one or more intermediate parts (e.g., an insulator, etc.) disposed between the spacer 3702 and the back plate 3306 and/or the spacer 3702 and the PCB-socket assembly 3304. The spacer 3702 prevents the PCB-socket assembly 3304 from warping in a manner similar to the back plate 3306 (e.g., with profile 3500, etc.). In the illustrated example of FIG. 37, the spacer 3702 causes the PCB-socket assembly 3304 to warp in a manner substantially similar to the IC package 3302. In some such examples, by causing the PCB-socket assembly 3304 to not warp in a manner similar to the back plate 3306, the PCB-socket assembly 3304 and the IC package 3302 have complimentary to the shape profiles such that the distance between any two corresponding connectors (e.g., pins and lands) is approximately the same. In other words, the spacer 3702 reduces and/or eliminates the gap 1805 between the socket 1706 and the IC package 1708 shown in FIG. 18.

In the illustrated example of FIG. 37, the thickness of the spacer 3702 varies along the length of the component stack 3700. For example, the thickness profile of the spacer 3702 can be equal to the difference between the profile 3402 of the IC package 3302 of FIG. 34 and the profile 3500 of the PCB-socket assembly 3304 of FIG. 35. In the illustrated example of FIG. 37, the spacer 3702 has an example first face 3707 oriented towards the back plate 3306 that has an example first surface curvature profile 3708 and an example second face 3709 oriented towards the PCB socket assembly 3304 that has an example second surface curvature profile 3710. In the illustrated example of FIG. 37, the profiles 3708, 3710 have different curvatures (e.g., different arcs, different parabolas, etc.). In other examples, the profiles 3708, 3710 can have a same curvature profile and/or mirrored curvature profile. In the illustrated example of FIG. 37, the profiles 3708, 3710 are convex profiles. In other examples, the load profile of the spacer 3702 can have any other suitable shape.

The spacer 3702 can be composed of an insulative material (e.g., glass, quartz, alumina, rubber, an insulative polymer, silicon, etc.). In other examples, the spacer 3702 can be composed of any suitable material. In the illustrated example of FIG. 37, the spacer 3702 causes the internal load distribution 3704 (e.g., the socket loading, etc.) of the component stack 3700 to be approximately equal throughout the component stack, thereby improving the performance of the component stack 3700.

FIG. 38 is an illustration of an example component stack 3800 implemented in accordance with the teachings of this disclosure. In the illustrated example of FIG. 38, the component stack 3800 includes an example pre-shaped back plate 3802, the IC package 3302 of FIG. 33, and the PCB-socket assembly 3304 of FIG. 33. In the illustrated example of FIG. 38, the component stack 3800 has an example internal load distribution 3804. In the illustrated example of FIG. 38, the back plate 3802 has an example surface curvature profile 3806. For example, the profile 3806 can be based on the difference between the profile 3402 of the IC package 3302 of FIG. 34 and the profile 3500 of the PCB-socket assembly 3304 of FIG. 35. Additionally or alternatively, the profile 3806 can be such that the warpage associated with the tightening of the fasteners of the component stack 3800 (e.g., the fasteners 1716A, 1716B, 1716C, 1716D of FIG. 17, etc.) causes the pre-shaped back plate 3802 to be flat and/or planar. In some examples, the pre-shaped back plate 3802 is planar when under the compression. In some examples, the pre-shaped back plate 3802 enables the PCB-socket assembly 3304 to have a shape profile (when under the compression) that is complimentary to the shape profile of the IC package 3302 such that the distance between any two corresponding connectors (e.g., pins and lands) is approximately the same. In other words, the pre-shaped back plate 3802 reduces and/or eliminates the gap 1805 between the socket 1706 and the IC package 1708 shown in FIG. 18.

In some examples, the pre-shaped back plate 3802 can be implemented by the pre-shaped back plate 2600 of FIGS. 26-29. In other examples, the pre-shaped back plate 3802 can be implemented by any other suitable back plate. In the illustrated example of FIG. 38 the pre-shaped back plate 3802 causes the internal load distribution 3804 (e.g., the socket loading, etc.) of the component stack 3800 to be approximately equal throughout the component stack, thereby improving the performance of the component stack 3800.

FIG. 39 is a flow diagram of example operations 3900 that can be used to assemble the back plate and spacer of FIG. 37. The operations 3900 begin at block 3902, at which the printed circuit board is placed. For example, the printed circuit board (e.g., the PCB 1712 of FIG. 17, the PCB of the PCB-socket assembly 3304 of FIG. 37, etc.) can be manufactured via printing, lamination, etching, drilling, plating, coating, and/or any other suitable manufacturing method. In some examples, after the PCB is manufactured, the PCB can be used as the base on which the other elements of the component stack (e.g., the component stack 3800, etc.) can be assembled thereon. At block 3904, the spacer 3702 is provided. For example, the spacer 3702 can be formed via machining, additive manufacturing, casting, blowing, lamination, and/or any other suitable manufacturing process. In some examples, the spacer 3702 can be composed of multiple components. In some such examples, the components of the spacer 3702 can be coupled via any suitable method (e.g., the one or more fasteners, one or more welds, one or more chemical adhesives, one or more press fits, one or more shrink fits, etc.). In other examples, the components of the spacer 3702 can be retained via the compressive force (e.g., the compressive force 1803, etc.) associated with the tightening of the fasteners (e.g., the fasteners 1716A, 1716B, 1716C, 1716D, etc.) (block 3916). In some examples, the spacer 3702 can be formed with the convex surface profiles 3708, 3710 such that the thickness of the spacer 3702 varies along the length of the spacer 3702. In other examples, the spacer 3702 can have any other suitable shape.

At block 3906, a back plate assembly including the spacer 3702 and a backplate (e.g., the back plate 3306 of FIG. 37, etc.) is assembled. For example, the spacer 3702 can be disposed on a top surface of the back plate 3306. In some examples, the spacer 3702 can be coupled to the back plate 3306 via one or more fasteners, one or more welds, one or more chemical adhesives, one or more press fits, one or more shrink fits, etc. In other examples, the spacer 3702 can be retained on the back plate 3306 via the compressive force (e.g., the compressive force 1803, etc.) of the fasteners (e.g., the fasteners 1716A, 1716B, 1716C, 1716D, etc.) (block 3916).

At block 3908, a PCB-socket assembly 3304 is formed by coupling a socket (e.g., the socket 1706, etc.) to the PCB (e.g., the PCB 1712, etc.). For example, the socket 1706 can be electrically coupled to the PCB via one or more cables, via soldering, via one or more pins, and/or any other suitable method. At block 3910, the back plate assembly is positioned beneath the PCB-socket assembly 3304. For example, the back plate assembly can be aligned such the center of the back plate assembly is aligned with the socket coupled to the PCB-socket assembly 3304 during the execution of block 3908. In other examples, the back plate assembly can be positioned at any other suitable location on the PCB. In some examples, the back plate assembly is retained in position against the PCB 1712 by being attached to the bolster plate 1710 on the opposite side of the PCB 1712 (as shown in FIG. 18).

At block 3912, the IC package (e.g., the IC package 3302 of FIG. 37, etc.) is coupled to the socket. For example, the IC package 3302 can be positioned with the socket of the PCB-socket assembly 3304. In some examples, holes of the IC package 3302 can be positioned to receive corresponding pins of the socket of the PCB-socket assembly 3304 to electrically couple the IC package 3302 to the PCB-socket assembly 3304. In other examples, the IC package 3302 and the PCB-socket assembly 3304 can be coupled by any other suitable means.

At block 3914, a heatsink (e.g., the heatsink 1702 of FIG. 17, etc.) is positioned on the IC package. For example, a pad or base of the heatsink can be positioned on a face of the IHS of the IC package 3302. In other examples, the heatsink can be positioned on any other suitable location on the IC package. At block 3916, the heatsink (e.g., the heatsink 1702 of FIG. 17, etc.) is coupled to the back plate (e.g., the back plate 3306, the back plate 1714, etc.), the coupling causing the deformation of the spacer 3702, the back plate, and the IC package 3302. For example, the heatsink 1702 and the back plate 3306 can be coupled via one or more polyetheretherketone (PEEK) nuts including anti-tilt features (e.g., the fasteners 1716A, 1716B, 1716C, 1716D, etc.) and/or one or more features of a bolster plate (e.g., the bolster plate 1710, etc.). Additionally or alternatively, any other suitable fasteners disposed at any suitable location on the PCB-socket assembly 3304, the back plate, and/or the IC package 3302 can be used. In some examples, the coupling of the heatsink 1702 and the back plate 3306 can exert a compressive force (e.g., the compressive force 1803 of FIG. 18, etc.) and thereby cause the features of the component stack 3700 to warp. In some such examples, the spacer 3702 prevents or reduces the formation of a gap (e.g., the gap 1805 of FIG. 18, etc.) and causes the relatively even internal load distribution (e.g., the internal load distribution 3704 of FIG. 37), thereby improving contact between the IC package 3302 and the socket of the PCB-socket assembly 3304.

FIG. 40 is a flow diagram of example operations 4000 that can be used to assemble the back plate assembly including spring sheets of FIG. 20-25. The operations 4000 begin at block 4002, at which the printed circuit board is placed. For example, the printed circuit board (e.g., the PCB 1712 of FIG. 17, etc.) can be manufactured via printing, lamination, etching, drilling, plating, coating, and/or any other suitable manufacturing method. In some examples, after the PCB is manufactured, the PCB 1712 can be used as the base on which the other elements of the component stack (e.g., a component stack associated with the back plate assembly 2000 of FIG. 20, a component stack associated with the back plate assembly 2300 of FIG. 23, a component stack associated with the back plate assembly 2400 of FIG. 24, etc.) can be assembled thereon.

At block 4004, one or more spring sheet(s) (e.g., the spring sheet 2002 of FIGS. 20-22, the spring sheets 2302, 2304, 2306, the spring sheet 2402 of FIG. 24, the spring sheet 2501 of FIG. 25, etc.) is/are provided. For example, the spring sheet can be formed via stamping, extrusion, and/or any other suitable manufacturing method. At block 4006, the one or more spring sheet(s) are coupled to the back plates (e.g., the back plate 2001 of FIGS. 20-22, the back plate 2301 of FIG. 23, the back plate 2401 of FIG. 24, the back plate 2500 of FIG. 25, etc.). For example, the one or more spring sheet(s) can be coupled at an example center of the back plate and/or at the edges of the back plate. In other examples, the one or more spring sheet(s) can be coupled at any other suitable location on the back plate. In some examples, the one or more spring sheets can be coupled to the back plate via one or more welds, one or more fasteners, one or more chemical adhesives, a press fit into a corresponding feature of the back plate, a shrink fit into a corresponding feature of the back plate, and/or a combination thereof.

At block 4008, a PCB-socket assembly 3304 is formed by coupling a socket (e.g., the socket 1706, etc.) to the PCB (e.g., the PCB 1712, etc.). For example, the socket 1706 can be electrically coupled to the PCB via one or more cables, via soldering, via one or more pins, and/or any other suitable method. At block 4010, the back plate assembly is positioned beneath the PCB-socket assembly 3304. For example, the back plate assembly can be aligned such the center of the back plate assembly is aligned with the socket of the PCB-socket assembly 3304 during the execution of block 4008. In other examples, the back plate assembly can be positioned at any other suitable location on the PCB-socket assembly 3304. In some examples, the back plate assembly is retained in position against the PCB 1712 by being attached to the bolster plate 1710 on the opposite side of the PCB 1712 (as shown in FIG. 18).

At block 4012, the IC package (e.g., the IC package 3302 of FIG. 33, etc.) is coupled to the socket. For example, the IC package 3302 can be positioned with the socket of the PCB-socket assembly 3304. In some examples, holes of the IC package 3302 can be positioned to receive corresponding pins of the socket of the PCB-socket assembly 3304 to electrically couple the IC package 3302 to the PCB-socket assembly 3304. In other examples, the IC package 3302 and the PCB-socket assembly 3304 can be coupled by any other suitable means. At block 4014, a heatsink (e.g., the heatsink 1702 of FIG. 17, etc.) is positioned on IC package. For example, a pad or base of the heatsink can be positioned on a face of the IHS of the IC package 3302. In other examples, the heatsink can be positioned on any other suitable location on the IC package.

At block 4016, the heatsink (e.g., the heatsink 1702 of FIG. 17, etc.) is coupled to the back plate (e.g., the back plate 3306, the back plate 1714, etc.), the coupling causing the deformation of the spring sheet(s), the back plate, and the IC package 3302. For example, the heatsink 1702 and the back plate 3306 can be coupled via one or more polyetheretherketone (PEEK) nuts including anti-tilt features (e.g., the fasteners 1716A, 1716B, 1716C, 1716D, etc.) and/or one or more features associate with a bolster plate (e.g., the bolster plate 1710, etc.). Additionally or alternatively, any other suitable fasteners disposed at any suitable location on the PCB-socket assembly 3304, the back plate, and/or the IC package 3302 can be used. In some examples, the coupling of the heatsink 1702 and the back plate 3306 can exert a compressive force (e.g., the compressive force 1803 of FIG. 18, etc.) and thereby cause the features of the component stack 3600 to warp. In some examples, the spring sheet(s) exert a corresponding force on the PCB-socket assembly 3304 and the back plate 3306, thereby preventing the PCB-socket assembly 3304 from undergoing warpage by the back plate 3306. In some such examples, the spring prevents or reduces the formation of a gap (e.g., the gap 1805 of FIG. 18, etc.) and causes the relatively even internal load distribution (e.g., the internal load distribution 3704 of FIG. 37), thereby improving contact between the IC package 3302 and the socket of the PCB-socket assembly 3304.

FIG. 41 is a flow diagram of example operations 4100 that can be used to assemble the back plate spring sheet assemblies of FIG. 26-29. The operations 4100 begin at block 4102, at which the printed circuit board is placed. For example, the printed circuit board (e.g., the PCB 1712 of FIG. 17, etc.) can be manufactured via printing, lamination, etching, drilling, plating, coating, and/or any other suitable manufacturing method. In some examples, after the PCB is manufactured, the PCB 1712 can be used as the base on which the other elements of the component stack (e.g., the component stack associated with the back plate assembly 2800 of FIG. 28, the component stack 3800 of FIG. 38, etc.) can be assembled thereon.

At block 4104, the back plate (e.g., the pre-shaped back plate 2600 of FIGS. 26-29, the pre-shaped back plate 3802 of FIG. 38, etc.) is provided. For example, the back plate 2600 can be formed of multiple layers composed of materials with different thermal properties (e.g., coefficients of thermal expansion, etc.) that are planarly bounded at an elevated temperature. In some such examples, when the back plate is cooled, the contraction of the layers caused the back-plate to assume a curved profile. In other examples, the pre-shaped back plate can be formed in any other suitable manner.

At block 4106, a PCB-socket assembly 3304 is formed by coupling a socket (e.g., the socket 1706, etc.) to the PCB (e.g., the PCB 1712, etc.). For example, the socket 1706 can be electrically coupled to the PCB via one or more cables, via soldering, via one or more pins, and/or any other suitable method. At block 4108, the back plate (e.g., the pre-shaped back plate 2600, the pre-shape back plate 3802, etc.) is positioned beneath the PCB-socket assembly 3304. For example, the back plate can be aligned such the center of the back plate assembly is aligned with the socket of the PCB-socket assembly 3304 during the execution of block 3906. In other examples, the back plate can be positioned at any other suitable location on the PCB-socket assembly 3304. In some examples, the back plate assembly is retained in position against the PCB 1712 by being attached to the bolster plate 1710 on the opposite side of the PCB 1712 (as shown in FIG. 18).

At block 4110, the IC package (e.g., the IC package 3302 of FIG. 38, etc.) is coupled to the socket. For example, the IC package 3302 can be positioned with the socket of the PCB-socket assembly 3304. In some examples, holes of the IC package 3302 can be positioned to receive corresponding pins of the socket of the PCB-socket assembly 3304 to electrically couple the IC package 3302 to the PCB-socket assembly 3304. In other examples, the IC package 3302 and the PCB-socket assembly 3304 can be coupled by any other suitable means. At block 4112, a heatsink (e.g., the heatsink 1702 of FIG. 17, etc.) is positioned on IC package. For example, a pad or base of the heatsink can be positioned on a face of the IHS of the IC package 3302. In other examples, the heatsink can be positioned on any other suitable location on the IC package.

At block 4114, the heatsink (e.g., the heatsink 1702 of FIG. 17, etc.) is coupled to the pre-shaped back plate, the coupling causing the deformation of the PCB-socket assembly 3304, the back plate, and the IC package 3302. For example, the heatsink 1702 and the back plate can be coupled via one or more polyetheretherketone (PEEK) nuts including anti-tilt features (e.g., the fasteners 1716A, 1716B, 1716C, 1716D, etc.) one or more features associate with a bolster plate (e.g., the bolster plate 1710, etc.). Additionally or alternatively, any other suitable fasteners disposed at any suitable location on the PCB-socket assembly 3304, the back plate, and/or the IC package 3302 can be used. In some examples, the coupling of the heatsink 1702 and the back plate 3306 can exert a compressive force (e.g., the compressive force 1803 of FIG. 18, etc.) and thereby cause the features of the component stack 3600 to warp. In some examples, the compressive force 1803 can cause the back plate to warp to a planar position, thereby ensuring some or all of the other features of the component stack have congruent profiles (e.g., the PCB-socket assembly 3304, the package 3302, etc.). In some such examples, the pre-shaped back plate prevents or reduces the formation of a gap (e.g., the gap 1805 of FIG. 18, etc.) and causes the relatively even internal load distribution (e.g., the internal load distribution 3804 of FIG. 38, thereby improving contact between the IC package 3302 and the socket of the PCB-socket assembly 3304.

Although the example operations 3900, 4000, 4100 are described with reference to the flowcharts illustrated in FIGS. 36, 40, and 41, many other methods of assembling the apparatus disclosed herein may alternatively be used. For example, the order of execution of the blocks may be changed, and/or some of the blocks described may be changed, eliminated, or combined.

The example component stack assemblies described herein with reference to FIGS. 20-41 depict back plates, PCBs, sockets, and/or IC packages in various warped and non-warped states. It should be understood that this warpage is for illustrative purposes only. In other examples, the components of the component stacks may have other and/or no deformation when the fasteners associated therewith are tightened.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities and/or steps, the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities and/or steps, the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements or method actions may be implemented by, e.g., the same entity or object. Additionally, although individual features may be included in different examples or claims, these may possibly be combined, and the inclusion in different examples or claims does not imply that a combination of features is not feasible and/or advantageous.

From the foregoing, it will be appreciated that example systems, methods, apparatus, and articles of manufacture have been disclosed that improve the contact force been the sockets of PCBs and the integrated circuit packages coupled thereto. Examples disclosed herein mitigate (e.g., prevent, etc.) the formation of the gap between sockets and the integrated circuits. Examples disclosed herein improve the pin contact between the socket and integrated, thereby improving the fidelity of communication therebetween and the overall performance of the component stack.

Example methods, apparatus, systems, and articles of manufacture to improve pin contact of a component stack are disclosed herein. further examples and combinations thereof include the following:

Example 1 includes an apparatus comprising a back plate, a circuit board disposed between the back plate and a socket, and a spring sheet disposed between the back plate and the circuit board.

Example 2 includes the apparatus of example 1, wherein the spring sheet directly abuts the back plate.

Example 3 includes the apparatus of example 1, wherein the spring sheet has a first surface to face towards the back plate and a second surface to face towards the circuit board, the first surface having a concave curvature.

Example 4 includes the apparatus of example 1, wherein the spring sheet has a first surface to face towards the back plate and a second surface to face towards the circuit board, a first point on the first surface to be spaced a first distance away from the back plate, a second point on the first surface to be spaced a second distance away from the back plate, the first distance greater than the second distance.

Example 5 includes the apparatus of example 1, wherein the spring sheet is a first spring sheet, the first spring sheet disposed adjacent to a first location of the back plate, the apparatus further including a second spring sheet disposed adjacent to a second location.

Example 6 includes the apparatus of example 5, wherein the first location is closer to a center of the socket than the second location.

Example 7 includes the apparatus of example 6, wherein the first spring sheet applies a tensional force to the back plate and the second spring sheet damps vibration associated with the back plate.

Example 8 includes the apparatus of example 1, wherein the spring sheet includes a first spring location having a first curvature, a second spring location having a second curvature, and an intermediate portion coupling the first spring location and the second spring location.

Example 9 includes the apparatus of example 8, wherein the first spring location is closer to a center of the socket than the second spring location.

Example 10 includes the apparatus of example 8, wherein the first spring location applies a tensional force to the socket and the second spring location damps vibration associated with the socket.

Example 11 includes the apparatus of example 1, wherein the spring sheet includes a first end fixedly coupled to the back plate.

Example 12 includes the apparatus of example 1, wherein the spring sheet is to apply a force on the circuit board near a center of the socket.

Example 13 includes the apparatus of example 12, wherein the force is to cause the socket to have a profile defined by a convex surface facing away from the circuit board.

Example 14 includes the apparatus of example 13, wherein the convex surface is to be complimentary to a warped surface of an interfacing integrated circuit package.

Example 15 includes an apparatus comprising a back plate, a socket including a plurality of pins, a circuit board coupled to the socket, an integrated circuit package interfaced with the socket via the pins, and a spring sheet disposed between the back plate and the circuit board.

Example 16 includes the apparatus of example 15, wherein the spring sheet has a first surface to face towards the back plate and a second surface to face towards the circuit board, a first point on the second surface to be spaced a first distance away from the circuit board, a second point on the second surface to be spaced a second distance away from the circuit board, the first distance greater than the second distance.

Example 17 includes the apparatus of example 15, wherein the spring sheet is a first spring sheet, the first spring sheet disposed adjacent to a first location of the back plate, the apparatus further including a second spring sheet disposed adjacent to a second location.

Example 18 includes the apparatus of example 17, wherein the first spring sheet is larger than the second spring sheet.

Example 19 includes the apparatus of example 17, wherein the first spring sheet applies a tensional force to the tensional and the second spring sheet damps vibration associated with the back plate.

Example 20 includes the apparatus of example 15, further including a fastener compressively coupling the integrated circuit package to the socket.

Example 21 includes the apparatus of example 15, wherein the spring sheet includes a first spring location having a first curvature, a second spring location having a second curvature, and an intermediate portion coupling the first spring location and the second spring location.

Example 22 includes the apparatus of example 15, wherein the spring sheet is to urge the socket toward the integrated circuit.

Example 23 includes the apparatus of example 15, wherein the spring sheet has a first surface facing towards the back plate and a second surface facing towards the socket, the first surface having a concave curvature.

Example 24 includes a method comprising coupling a spring sheet to a back plate, coupling a socket to a first surface of a circuit board, and disposing the spring sheet next to the circuit board such that the spring sheet is between the circuit board and the back plate.

Example 25 includes the method of example 24, further including disposing an integrated circuit package within the socket, and applying, via a tightening of a fastener, a compressive force to the circuit board, IC package, the back plate, and the socket, the compressive force causing the socket and the IC package to warp in a complementary manner.

Example 26 includes the method of example 25, wherein the spring sheet is a first spring sheet, the coupling of the spring sheet including coupling the first spring sheet to a first location of the back plate, the method further including disposing a second spring sheet adjacent to a second location of the back plate.

Example 27 includes the method of example 26, wherein the first spring sheet increases contact between the IC package and the socket and the second spring sheet reduces vibration associated with the socket.

Example 28 includes an apparatus comprising a plate, a socket disposed on a first side of a circuit board, and a spacer disposed on a second side of the circuit board, the spacer between the plate and the circuit board.

Example 29 includes the apparatus of example 28, wherein the spacer has a thickness profile including a first thickness at a first location, and a second thickness at a second location, the first thickness different than the second thickness.

Example 30 includes the apparatus of example 29, wherein the first location is adjacent an edge of the spacer and the second location is adjacent a center of the spacer, the second thickness greater than the first thickness.

Example 31 includes the apparatus of example 30, wherein the thickness profile of the spacer includes a third thickness at a third location, the third location a same distance from the second location as the first location is from the second location, the second thickness greater than the third thickness.

Example 32 includes the apparatus of example 31, wherein the third thickness is substantially equal to the first thickness.

Example 33 includes the apparatus of example 32, wherein the spacer has a first face and a second face, and at least one of the first face and the second face has a convex profile.

Example 34 includes the apparatus of example 33, wherein the first face has a first curvature profile and the second face has a second curvature profile different than the first curvature profile.

Example 35 includes the apparatus of example 28, further including an integrated circuit (IC) package interfaced with the socket, and a fastener compressively coupling the IC package to the socket, the spacer retained via a compressive force of the fastener.

Example 36 includes the apparatus of example 28, wherein the spacer directly abuts at least one of the circuit board or the plate.

Example 37 includes an apparatus comprising a back plate, a socket including a pin, a circuit board to carry the socket, an integrated circuit package electrically coupled to the socket via the pin, and a spacer disposed between the back plate and the circuit board.

Example 38 includes the apparatus of example 37, wherein the spacer has a first thickness at a first location and a second thickness at a second location, the first thickness different than the second thickness.

Example 39 includes the apparatus of example 38, wherein the first location is closer to a center of the spacer than the second location is to the center of the spacer, the first thickness greater than the second thickness.

Example 40 includes the apparatus of example 39, wherein the spacer includes a third thickness at a third location, the third location a same distance from the second location as the first location is from the second location, the second thickness greater than the third thickness.

Example 41 includes the apparatus of example 40, wherein the third thickness has a substantially same thickness as the first thickness.

Example 42 includes the apparatus of example 37, wherein the spacer has a first face and a second face, and at least one of the first face and the second face has a convex curvature.

Example 43 includes the apparatus of example 42, wherein the first face has a first non-planar surface and the second face has a second non-planar surface different than the convex curvature.

Example 44 includes the apparatus of example 37, further including a fastener retaining the IC package on the socket, the spacer retained via a compressive force of the fastener.

Example 45 includes the apparatus of example 37, wherein the spacer directly abuts at least one of the circuit board or the back plate.

Example 46 includes a method comprising disposing a spacer on a back plate, coupling a socket to a first surface of a circuit board, and disposing the back plate adjacent the circuit board such that the spacer is between the circuit board and the back plate.

Example 47 includes the method of example 46, further including disposing an integrated circuit (IC) package within the socket, and applying, via a tightening of a fastener, a compressive force to the circuit board, IC package, the back plate, and the socket, the compressive force causing the socket and the IC package to warp in a complimentary manner.

Example 48 includes the method of example 46, wherein the spacer has a greater thickness near a center of a spacer than adjacent an edge of the spacer.

Example 49 includes the method of example 46, wherein the spacer is disposed such that the spacer directly abuts at least one of the circuit board or the back plate.

Example 50 includes an apparatus comprising a socket, a circuit board to carry the socket, and a back plate having a first surface to face towards the circuit board, the first surface being non-planar.

Example 51 includes the apparatus of example 50, wherein first surface has a convex curvature.

Example 52 includes the apparatus of example 50, wherein the back plate includes a first layer having a first thermal property, and a second layer having a second thermal property different than the first thermal property, the first surface being non-planar based on the difference between the first thermal property and the second thermal property.

Example 53 includes the apparatus of example 52, wherein at least one of the first thermal property or the second thermal property is a coefficient of thermal expansion.

Example 54 includes the apparatus of example 52, wherein the first layer has a first thickness and the second layer has a second thickness, the first thickness different than the second thickness.

Example 55 includes the apparatus of example 54, wherein the back plate has a third thickness, the third thickness equal to a sum of the first thickness and the second thickness.

Example 56 includes the apparatus of example 52, wherein the back plate has a first face, the first layer, has a second face, and the second layer has a third face, the first face, the second face and the third facing have a substantially equal surface area.

Example 57 includes the apparatus of example 50 wherein the back plate includes a smart metal alloy.

Example 58 includes the apparatus of example 50, wherein the first surface is non-planar when the back plate is at a first temperature and the first surface is planar when the back plate is at second temperature, the second temperature higher than the first temperature.

Example 59 includes the apparatus of example 58, wherein the first temperature is a room temperature.

Example 60 includes an apparatus comprising a circuit board, a socket to be supported on a first side of the circuit board, and a back plate to be supported on a second side of the circuit board opposite the socket, the back plate including a first layer having a first coefficient of thermal expansion, and a second layer having a second coefficient of thermal expansion , the first and second layers bonded together such that a surface of the back plate changes shape in response to a change in temperature based on a difference in the first coefficient of thermal expansion and the second coefficient of thermal expansion, both the first and second layers extending a same distance between opposing edges of the back plate.

Example 61 includes the apparatus of example 60, wherein the back plate includes a third layer disposed between the first layer and the second layer.

Example 62 includes the apparatus of example 60, wherein the back plate has a third thickness, the third thickness having substantially a same thickness as a sum of a first thickness of the first layer and a second thickness of the second layer.

Example 63 includes the apparatus of example 60, wherein the surface of the back plate is a first surface, the back plate including a second surface opposite the first surface, the first surface corresponding to the first layer, and the second surface corresponding to the second layer.

Example 64 includes the apparatus of example 60, wherein the first coefficient of thermal expansion is lesser than the second coefficient of thermal expansion, the first layer to be between the second layer and the circuit board.

Example 65 includes a method comprising providing a back plate having a convex curvature, coupling a socket to a first surface of a circuit board, and disposing the back plate on the circuit board with the convex curvature towards the circuit board.

Example 66 includes the method of example 65, wherein the providing the back plate includes providing a first layer having a first coefficient of thermal expansion, and providing a second layer having a second coefficient of thermal expansion different than the first coefficient of thermal expansion, the difference between the first coefficient of thermal expansion and the second coefficient of thermal expansion causing the convex curvature.

Example 67 includes the method of example 66, further including joining the first layer and the second layer at an elevated temperature.

Example 68 includes the method of example 67, wherein the back plate has a third thickness, the third thickness equal to a sum of a first thickness of the first layer and a second thickness of the second layer.

Example 69 includes an apparatus comprising a circuit board, means for receiving an integrated circuit (IC) package, the receiving means carried by the circuit board, and means for increasing contact between the receiving means and the IC package, the circuit board between the contact increasing means and the receiving means, the contact increasing means to urge a center of the receiving means towards the IC package.

Example 70 includes the apparatus of example 69, wherein the contact increasing means causing a load distribution between the IC package and the receiving means to be substantially equal across the IC package.

Example 71 includes the apparatus of example 69, further including a back plate.

Example 72 includes the apparatus of example 71, wherein the back plate includes the contact increasing means.

Example 73 includes the apparatus of example 71, wherein the contact increasing means is to be disposed between the back plate and the circuit board.

The following claims are hereby incorporated into this Detailed Description by this reference. Although certain example systems, methods, apparatus, and articles of manufacture have been disclosed herein, the scope of coverage of this patent is not limited thereto. On the contrary, this patent covers all systems, methods, apparatus, and articles of manufacture fairly falling within the scope of the claims of this patent.

1. An apparatus comprising:
a back plate;
a circuit board disposed between the back plate and a socket; and
a spring sheet disposed between the back plate and the circuit board.

2. The apparatus of claim 1, wherein the spring sheet directly abuts the back plate.

3. The apparatus of claim 1, wherein the spring sheet has a first surface to face towards the back plate and a second surface to face towards the circuit board, the first surface having a concave curvature.

4. The apparatus of claim 1, wherein the spring sheet has a first surface to face towards the back plate and a second surface to face towards the circuit board, a first point on the first surface to be spaced a first distance away from the back plate, a second point on the first surface to be spaced a second distance away from the back plate, the first distance greater than the second distance.

5. The apparatus of claim 1, wherein the spring sheet is a first spring sheet, the first spring sheet disposed adjacent to a first location of the back plate, the apparatus further including a second spring sheet disposed adjacent to a second location.

6. The apparatus of claim 5, wherein the first location is closer to a center of the socket than the second location.

7. The apparatus of claim 6, wherein the first spring sheet applies a tensional force to the back plate and the second spring sheet damps vibration associated with the back plate.

8. The apparatus of claim 1, wherein the spring sheet includes:
a first spring location having a first curvature;
a second spring location having a second curvature; and
an intermediate portion coupling the first spring location and the second spring location.

9. The apparatus of claim 8, wherein the first spring location is closer to a center of the socket than the second spring location.

10. (canceled)

11. The apparatus of claim 1, wherein the spring sheet includes a first end fixedly coupled to the back plate.

12. The apparatus of claim 1, wherein the spring sheet is to apply a force on the circuit board near a center of the socket.

13. The apparatus of claim 12, wherein the force is to cause the socket to have a profile defined by a convex surface facing away from the circuit board.

14. The apparatus of claim 13, wherein the convex surface is to be complimentary to a warped surface of an interfacing integrated circuit package.

15. An apparatus comprising:
a back plate;
a socket including a plurality of pins;
a circuit board coupled to the socket;
an integrated circuit package interfaced with the socket via the pins; and
a spring sheet disposed between the back plate and the circuit board.

16. The apparatus of claim 15, wherein the spring sheet has a first surface to face towards the back plate and a second surface to face towards the circuit board, a first point on the second surface to be spaced a first distance away from the circuit board, a second point on the second surface to be spaced a second distance away from the circuit board, the first distance greater than the second distance.

17. The apparatus of claim 15, wherein the spring sheet is a first spring sheet, the first spring sheet disposed adjacent to a first location of the back plate, the apparatus further including a second spring sheet disposed adjacent to a second location.

18. The apparatus of claim 17, wherein the first spring sheet is larger than the second spring sheet.

19. (canceled)

20. The apparatus of claim 15, further including a fastener compressively coupling the integrated circuit package to the socket.

21. The apparatus of claim 15, wherein the spring sheet includes:
a first spring location having a first curvature;
a second spring location having a second curvature; and
an intermediate portion coupling the first spring location and the second spring location.

22. The apparatus of claim 15, wherein the spring sheet is to urge the socket toward the integrated circuit.

23. The apparatus of claim 15, wherein the spring sheet has a first surface facing towards the back plate and a second surface facing towards the socket, the first surface having a concave curvature.

24. A method comprising:
coupling a spring sheet to a back plate;
coupling a socket to a first surface of a circuit board; and
disposing the spring sheet next to the circuit board such that the spring sheet is between the circuit board and the back plate.

25. The method of claim 24, further including:
disposing an integrated circuit package within the socket; and
applying, via a tightening of a fastener, a compressive force to the circuit board, IC package, the back plate, and the socket, the compressive force causing the socket and the IC package to warp in a complementary manner.

26. The method of claim 25, wherein the spring sheet is a first spring sheet, the coupling of the spring sheet including coupling the first spring sheet to a first location of the back plate, the method further including disposing a second spring sheet adjacent to a second location of the back plate.

27.-68. (canceled)

69. An apparatus comprising:
a circuit board;
means for receiving an integrated circuit (IC) package, the receiving means carried by the circuit board; and
means for increasing contact between the receiving means and the IC package, the circuit board between the contact increasing means and the receiving means, the contact increasing means to urge a center of the receiving means towards the IC package.

70. The apparatus of claim 69, wherein the contact increasing means causing a load distribution between the IC package and the receiving means to be substantially equal across the IC package.

71. The apparatus of claim 69, further including a back plate.

72. The apparatus of claim 71, wherein the back plate includes the contact increasing means.

73. (canceled)
